(19) United States
(12) Patent Application Publication
(10) Pub. No.: US 2016/0218111 A1
(43) Pub. Date: Jul. 28, 2016

(54) MEMORY DEVICE AND METHOD FOR FABRICATING THE SAME

(71) Applicant: MACRONIX International Co., Ltd., Hsinchu (TW)

(72) Inventors: Chih-Chieh Cheng, Hsinchu (TW); Shih-Guei Yan, Hsinchu (TW); Wen-Jer Tsai, Hsinchu (TW)

(21) Appl. No.: 14/604,134

(22) Filed: Jan. 23, 2015

(51) Int. Cl. H01L 27/115; G11C 16/10; H01L 21/324; H01L 23/528; H01L 21/28; H01L 21/265; G11C 16/04; G11C 16/26

(52) U.S. Cl. CPC H01L 27/11568; G11C 16/0483; G11C 16/10; G11C 16/26; H01L 23/528; H01L 21/28282; H01L 21/26513; H01L 21/324

(57) ABSTRACT

A memory device is provided. The memory device includes a substrate, a plurality of semiconductor strip structures, a first doped region, a plurality of second doped regions, a plurality of first contacts, and a plurality of second contacts. Each of the semiconductor strip structures extends along a first direction. The first doped region includes a plurality of first portions and a second portion. Each of the first portions is located on a lower part of the corresponding semiconductor strip structure. The second portion is located on a surface of the substrate, and the first portions are connected to the second portion. Each of the second doped regions is located on an upper part of the corresponding semiconductor strip structure. Each of the first contacts is electrically connected to the second portion of the first doped region. Each of the second contacts is electrically connected to the corresponding second doped region.

### BACKGROUND OF THE INVENTION

1. Field of the Invention

The invention relates to a semiconductor device and a method of fabricating the same, and more particularly, the invention relates to a memory device and a method of fabricating the same.

2. Description of Related Art

A non-volatile memory can repeatedly perform operations of data storing, reading, and erasing, etc., and the data stored therein does not disappear even if the power supply is shut down. For this reason, the non-volatile memory has been used as the memory device necessary for various electronic products for maintaining normal operation when power is turned on.

However, with the reduction of the sizes of semiconductor devices, the short channel effect of the traditional horizontal memory device becomes worse. This effect will lead to the deterioration of the second bit effect and the program disturbance in the memory device. In order to avoid this problem, vertical memory devices have been developed and introduced in the recent years, wherein the channel length remains unchanged while the size is reduced, so as to prevent the short channel effect and improve the second bit effect and program disturbance.

In the vertical memory device, as the elements are stacked on each other to form the structure, the relative relationship between the elements and the configuration of the stack structure also become complicated. Therefore, how to simplify the relative relationship between the vertical memory devices and the configuration of the stack structure without sacrificing the operational performance is an issue that needs to be overcome.

### SUMMARY OF THE INVENTION

The invention provides a memory device and a fabricating method thereof, for simplifying a relative relationship between vertical memory devices and a configuration of a stack structure thereof without sacrificing operational performance and compatibility with the current fabricating processes.

The invention provides a memory device that includes a substrate, a plurality of semiconductor strip structures, a first doped region, a plurality of second doped regions, a plurality of word lines, a charge storage layer, a plurality of first contacts, a plurality of second contacts, a first conductive line, and a plurality of second conductive lines. The substrate includes a plurality of first blocks and a plurality of second blocks. The first blocks and the second blocks are alternated to each other, wherein each of the first blocks includes two first regions and a second region, and the second region is disposed between the two first regions. The semiconductor strip structures are disposed on the substrate. Each of the semiconductor strip structures extends along a first direction. The first doped region includes a plurality of first portions and a second portion. Each of the first portions is located on a lower part of the corresponding semiconductor strip structure. The second portion is located on a surface of the substrate, and the first portions are connected with the second portion. Each of the second doped regions is located on an upper part of the corresponding semiconductor strip structure. The word lines are disposed on the substrate in each of the first regions. Each of the word lines extends in a second direction and covers a portion of a sidewall and a portion of a top of each of the semiconductor strip structures. The first direction is different from the second direction. The charge storage layer is disposed between the semiconductor strip structures and the word lines. The first contacts are disposed in the second blocks and the second regions and are arranged along the first direction. Each of the first contacts is electrically connected with the second portion of the first doped region. The second contacts are disposed at least in the second regions. Each of the second contacts is electrically connected with the corresponding second doped region. The first conductive line is disposed on the substrate and extends in the first direction, and is electrically connected with the first contacts. The second conductive lines are disposed on the substrate. Each of the second conductive lines extends in the first direction and is electrically connected with the second contact on the corresponding semiconductor strip structure.

In an embodiment of the invention, each of the semiconductor strip structures includes a body region. Each of body regions is disposed between the second doped region and the first portion of the first doped region of the semiconductor strip structure. Moreover, the second blocks further include the second contacts therein.

In an embodiment of the invention, each of the semiconductor strip structures includes a first barrier layer and a second barrier layer. The first barrier layer is disposed between the body region and the first portion of the first doped region; and the second barrier layer is disposed between the body region and the second doped region.

In an embodiment of the invention, each of the second blocks includes a trench therein that extends in the second direction. Moreover, each of the semiconductor strip structures includes the body region. In the first blocks, each of the body regions is disposed between the second doped region and the first portion of the first doped region. In the second blocks, each of the body regions is disposed on the first portion of the first doped region, and the trench exposes the body region.

In an embodiment of the invention, a plurality of third contacts and a third conductive line are further included. Each of the third contacts is disposed in the second blocks and extends in the second direction, and each of the third contacts is electrically connected with the body region exposed by the trench. The third conductive line is disposed on the substrate and extends in the first direction, and is electrically connected with the third contacts.

In an embodiment of the invention, a plurality of local conductive lines are disposed in the first blocks at two sides of each third contact. Each of the local conductive lines extends in the first direction and is electrically connected with the second contact on the corresponding semiconductor strip structure. Moreover, each of the second conductive lines is disposed above the partial conductive line on the corresponding semiconductor strip structure and spans across the third contacts to be electrically connected with the corresponding partial conductive line through a plurality of fourth contacts.

In an embodiment of the invention, each of the semiconductor strip structures includes a first barrier layer disposed between the body region and the first portion of the first doped region; and a second barrier layer disposed between the body region and the second doped region.

The invention provides a fabricating method of a memory device, and the fabricating method includes the following. A substrate is provided. The substrate includes a plurality of first blocks and a plurality of second blocks, wherein the first blocks and the second blocks are alternated to each other. Each of the first blocks includes two first regions and a second region, and the second region is disposed between the two first regions. A plurality of semiconductor strip structures are formed on the substrate, wherein each of the semiconductor strip structures extends in a first direction. A first doped region is formed, and the first doped region includes a plurality of first portions and a second portion. Each of the first portions is located on a lower part of the corresponding semiconductor strip structure. The second portion is located on a surface of the substrate, and the first portions are connected with the second portion. A plurality of second doped regions are formed on an upper part of each of the semiconductor strip structures. A plurality of word lines are formed on the substrate in each of the first regions. Each of the word lines extends in a second direction and covers a portion of a sidewall and a portion of a top of each of the semiconductor strip structures. The first direction is different from the second direction. A charge storage layer is formed between the semiconductor strip structures and the word lines. A plurality of first contacts are formed in the second blocks and the second regions and arranged in the first direction, wherein each of the first contacts is electrically connected with the second portion of the first doped region. A plurality of second contacts are formed at least in the second regions. Each of the second contacts is electrically connected with the corresponding second doped region. A first conductive line is formed on the substrate. The first conductive line extends in the first direction and is electrically connected with the first contacts. A plurality of second conductive lines are formed on the substrate. Each of the second conductive lines extends in the first direction and is electrically connected with the second contact on the corresponding semiconductor strip structure.

In an embodiment of the invention, a method of forming the semiconductor strip structures, the first doped region, and the second doped regions includes the following. A portion of the substrate is patterned to form the semiconductor strip structures. An ion implantation process is performed to implant a dopant into the upper part of each of the semiconductor strip structures and a surface of the substrate. A thermal annealing process is performed to form the first doped region and the second doped regions.

In an embodiment of the invention, the method of forming the semiconductor strip structures, the first doped region, and the second doped regions includes the following. An ion implantation process is performed to form the second portion of the first doped region on the surface of the substrate. A stack layer is formed on the substrate, wherein the stack layer includes a first doped layer, a body layer, and a second doped layer in sequence from bottom to top. The stack layer is patterned to form the first portions of the first doped region, a plurality of body regions, and the second doped regions.

In an embodiment of the invention, the fabricating method further includes forming the second contacts in the second blocks.

In an embodiment of the invention, the fabricating method further includes removing a portion of the semiconductor strip structures in the second blocks to form a trench. The trench extends in the second direction and exposes the body region of the corresponding semiconductor strip structure.

In an embodiment of the invention, the fabricating method further includes the following. A plurality of third contacts are formed in the second blocks. Each of third contacts extends in the second direction, and is electrically connected with the body region exposed by the trench. A third conductive line is formed on the substrate, wherein the third conductive line extends in the first direction and is electrically connected with the third contacts.

In an embodiment of the invention, the fabricating method further includes forming a plurality of local conductive lines in the first blocks at two sides each third contact. Each of the local conductive lines extends in the first direction and is electrically connected with the second contact on the corresponding semiconductor strip structure. Moreover, each of the second conductive lines is disposed above the partial conductive line on the corresponding semiconductor strip structure and spans across the third contacts to be electrically connected with the corresponding partial conductive line through a plurality of fourth contacts.

In an embodiment of the invention, the stack layer includes the first doped layer, the first barrier layer, the body layer, the second barrier layer, and the second doped layer n sequence from bottom to top.

The invention provides a memory device that includes a substrate, a plurality of semiconductor strip structures, a first doped region, a plurality of second doped regions, a first conductive line, and a plurality of second conductive lines. The substrate includes a plurality of first blocks and a plurality of second blocks. The first blocks and the second blocks are alternated to each other, each of the first blocks comprises two first regions and a second region, and the first regions and the second regions is disposed between the two first regions. The semiconductor strip structures are disposed on the substrate. Each of the semiconductor strip structures extends in a first direction. The first doped region includes a plurality of first portions and a second portion. Each of the first portions is disposed at a lower part of the corresponding semiconductor strip structure. The second portion is disposed on a surface of the substrate, and the first portions are connected with the second portion. Each of the second doped regions is disposed at an upper part of the corresponding semiconductor strip structure. The first conductive line is disposed on the substrate. The first conductive line extends in the first direction and is electrically connected with the second portion of the first doped region in the second blocks and the second regions. Moreover, the second conductive lines are disposed on the substrate. Each of the second conductive lines extends in the first direction and is electrically connected with the second doped regions on the corresponding semiconductor strip structure in the second regions.

In an embodiment of the invention, each of the second conductive lines is further electrically connected with the second doped region on the corresponding semiconductor strip structure in the second regions.

In an embodiment of the invention, each of the second blocks includes a trench therein that extends in the second direction. Each of the semiconductor strip structures includes a body region. In the first blocks, each of the body regions is disposed between the second doped region and the first portion of the first doped region. In the second blocks, each of the body regions is disposed on the first portion of the first doped region, and the trench exposes the body region. A third conductive line is disposed on the substrate. The third conductive line extends in the first direction and is electrically connected with the body regions exposed by the trench in the second blocks.

In an embodiment of the invention, the memory device further includes a plurality of local conductive lines that are disposed in the first blocks. Each of the local conductive lines extends in the first direction and is electrically connected with the second doped region on the corresponding semiconductor strip structure. Each of the second conductive lines is disposed above the local conductive lines on the corresponding semiconductor strip structure and spans across the second blocks to be electrically connected with the corresponding local conductive lines in the first blocks.

In an embodiment of the invention, each of the semiconductor strip structures includes a first barrier layer, the body region, and a second barrier layer. The first barrier layer is disposed between the body region and the first portion of the first doped region. The body region is disposed between the second doped region and the first portion of the first doped region. The second barrier layer is disposed between the body region and the second doped region.

The invention further provides a memory array including the aforementioned memory device. The memory array includes a plurality of memory cells, a plurality of bit lines, a plurality of common source lines, and a source line. The memory cells are arranged in an array of a plurality of columns and a plurality of rows and include the first doped region as a source and the second doped regions as a drain. Each of the bit lines is coupled to the second doped regions of the memory cells of the same column. Each of the common source lines is coupled to the first doped region of the memory cells of the same row. The source line is coupled to the common source lines and electrically connected with the first doped region of the memory cells. Each word line is coupled to a plurality of gates of the memory cells of the same row.

In an embodiment of the invention, the memory array further includes a body line coupled to a plurality of body regions of the memory cells.

The invention further provides an operating method of the memory array. The operating method includes: selecting at least one memory cell, applying a first voltage to a word lines corresponding to the selected at least one memory cell, applying a second voltage to a bit lines corresponding to the selected at least one memory cell, and applying a third voltage to the source line of the memory array.

In an embodiment of the invention, the operating method further includes: applying a fourth voltage to a body line corresponding to the selected at least one memory cell.

Based on the above, the first portions and the second portion of the first doped region provided by the invention are connected with each other. Thus, the first doped region in each of the semiconductor strip structures is connected with one another. Further, because the first contact is electrically connected with the second portion of the first doped region, the first contact is electrically connected with the first doped region in each semiconductor strip structure. Accordingly, the relative relationship between the vertical memory devices and the configuration of the stack structure are simplified significantly without sacrificing the operational performance and the compatibility with the current fabricating processes.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1A to FIG. 1D are top views illustrating a fabricating method of a memory device according to the first embodiment of the invention.

FIG. 2A to FIG. 2D are cross-sectional views of FIG. 1A to FIG. 1D along the line A-A′.

FIG. 3A to FIG. 3D are cross-sectional views of FIG. 1A to FIG. 1D along the line B-B′.

FIG. 4A to FIG. 4D are cross-sectional views of FIG. 1A to FIG. 1D along the line C-C′.

FIG. 5A to FIG. 5D are cross-sectional views of FIG. 1A to FIG. 1D along the line D-D′.

FIG. 6A to FIG. 6E are top views illustrating a fabricating process of a memory device according to the second embodiment of the invention.

FIG. 7A to FIG. 7E are cross-sectional views of FIG. 6A to FIG. 6E along the line A-A′.

FIG. 8A to FIG. 8E are cross-sectional views of FIG. 6A to FIG. 6E along the line B-B′.

FIG. 9A to FIG. 9E are cross-sectional views of FIG. 6A to FIG. 6E along the line C-C′.

FIG. 10A to FIG. 10E are cross-sectional views of FIG. 6A to FIG. 6E along the line E-E′.

FIG. 11A is a schematic view illustrating a memory array structure according to the first embodiment of the invention.

FIG. 11B is a schematic view illustrating a memory array structure according to the second embodiment of the invention.

FIG. 12A to FIG. 12B are schematic views illustrating a memory device of a reverse reading operation according to an embodiment of the invention.

FIG. 13A to FIG. 13B are schematic views illustrating a memory device of a channel hot electron injection (CHEI) operation according to an embodiment of the invention.

FIG. 14A to FIG. 14B are schematic views illustrating a memory device of a band-to-band tunneling induced hot hole (BTBT HH) operation according to an embodiment of the invention.

FIG. 15A to FIG. 15B are schematic views illustrating a memory device of an FN hole injection operation according to an embodiment of the invention.

FIG. 16A to FIG. 16B are schematic views illustrating a memory device of an FN electron injection operation according to an embodiment of the invention.

### DESCRIPTION OF THE EMBODIMENTS

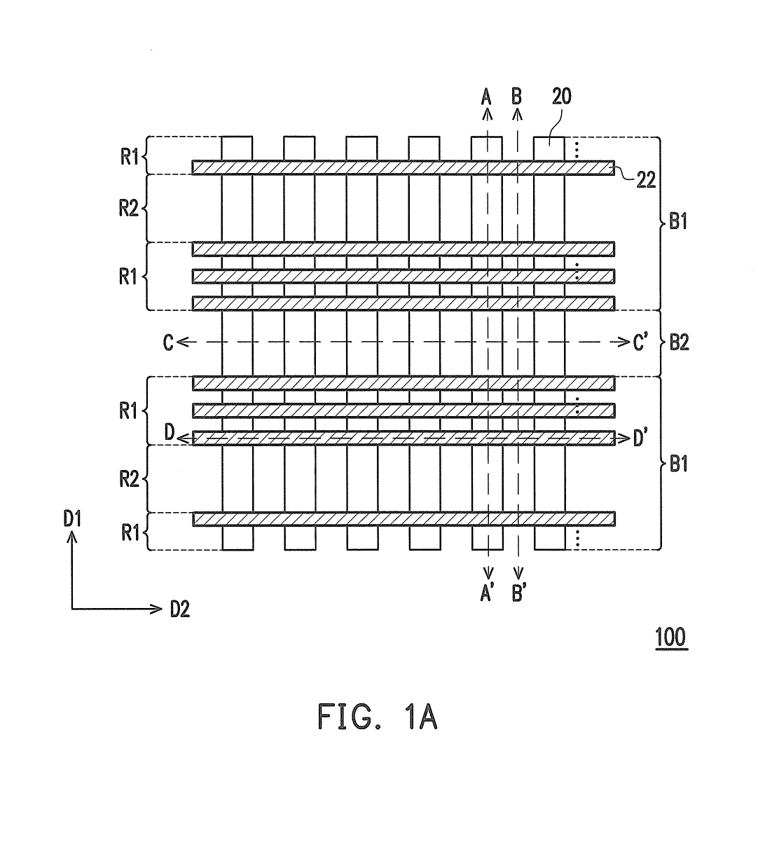

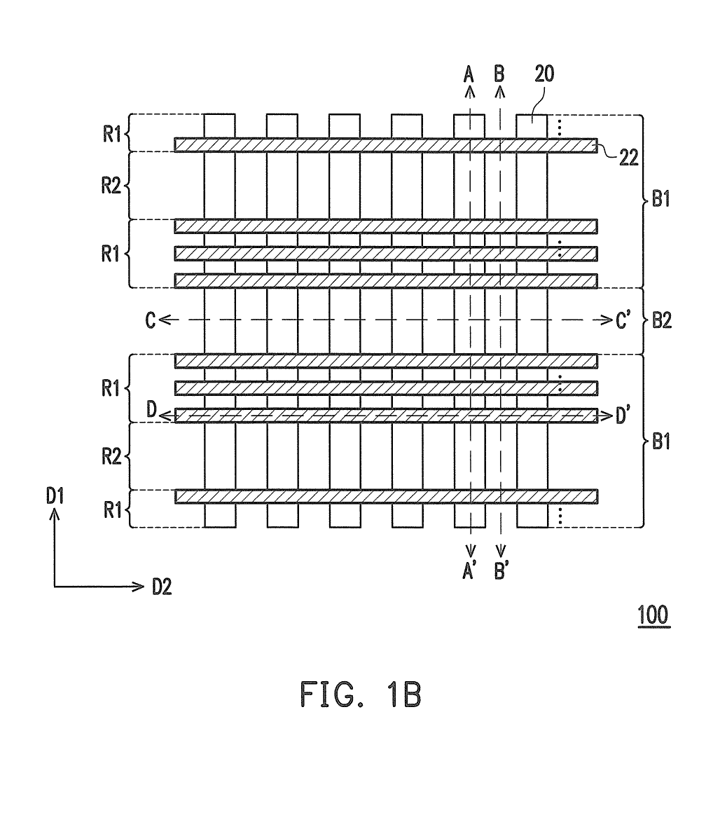

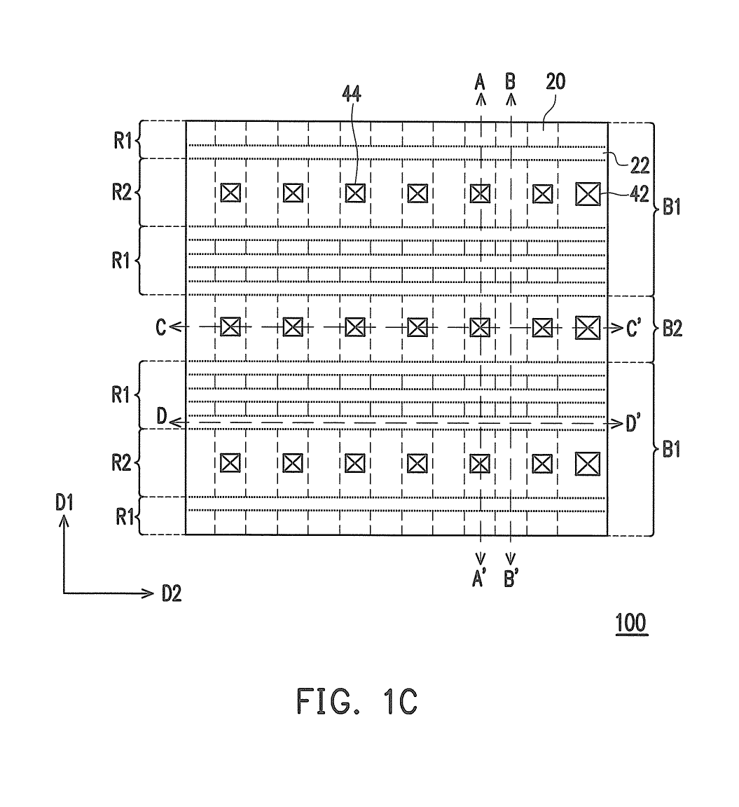

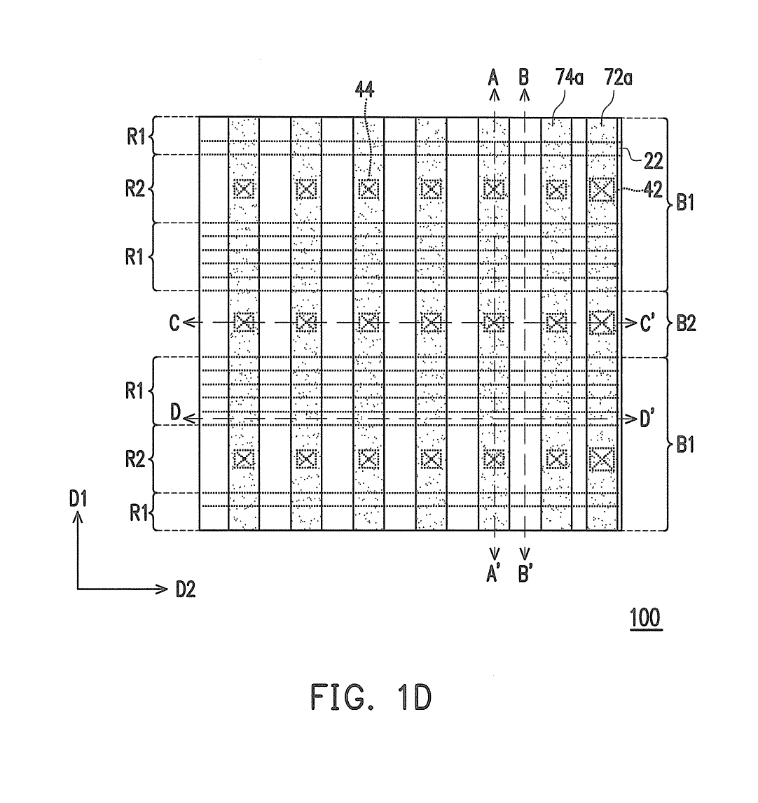

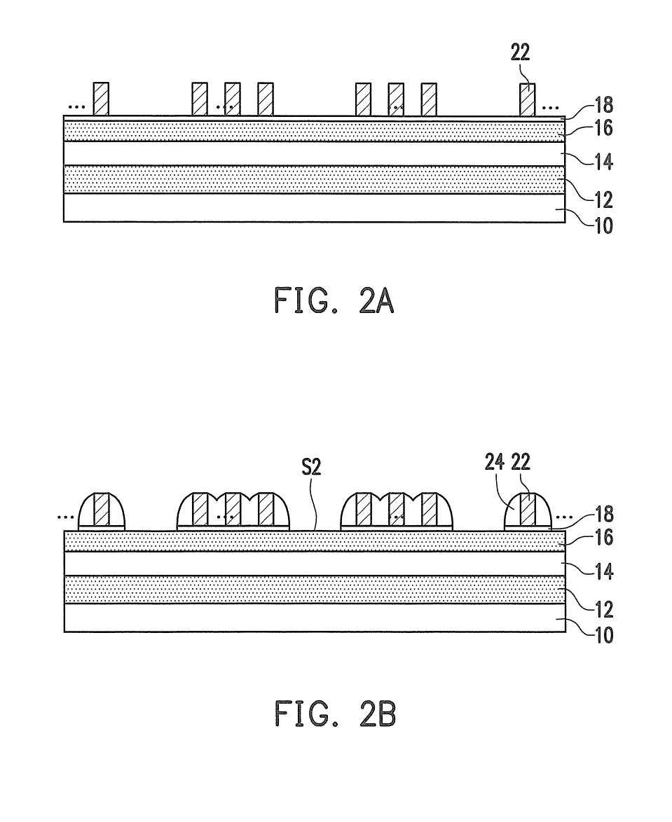

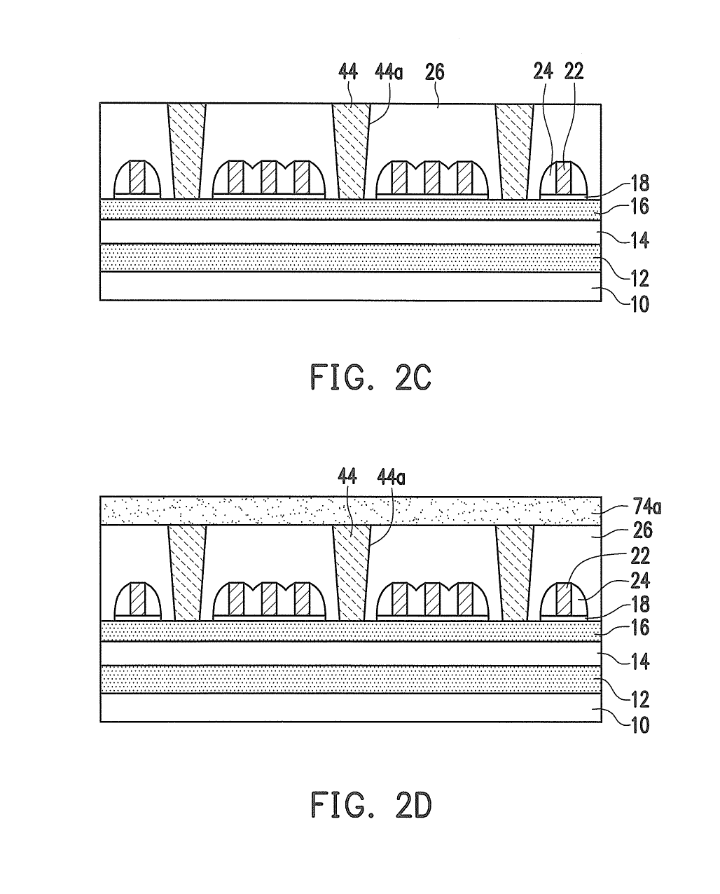

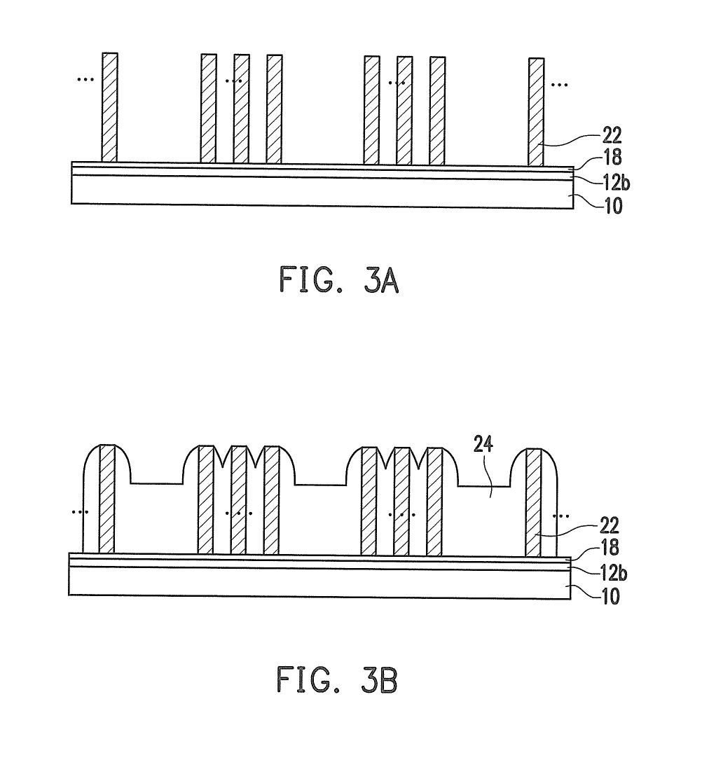

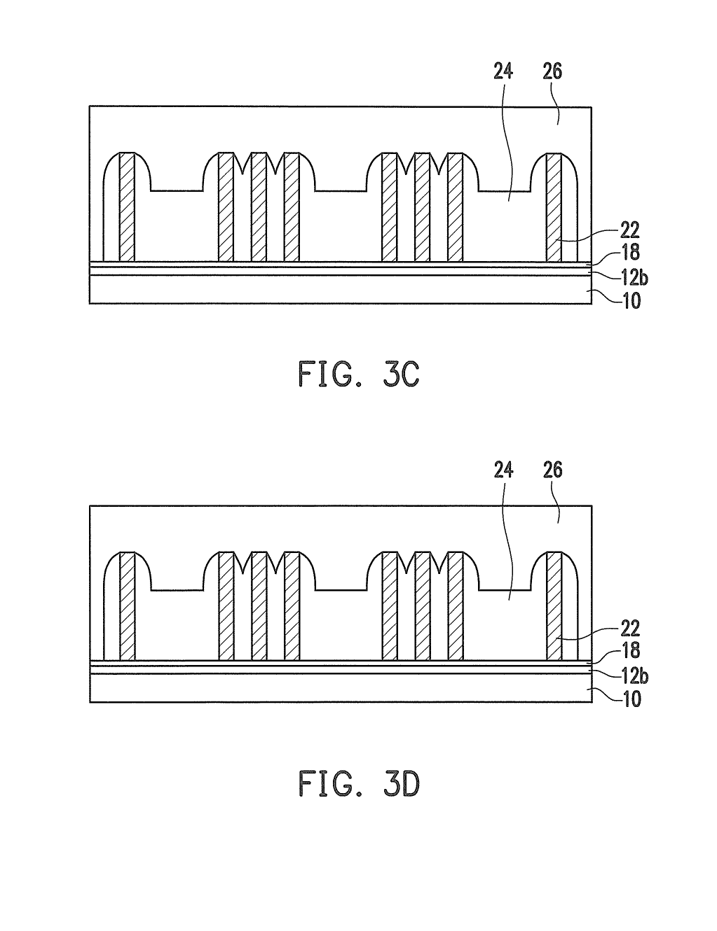

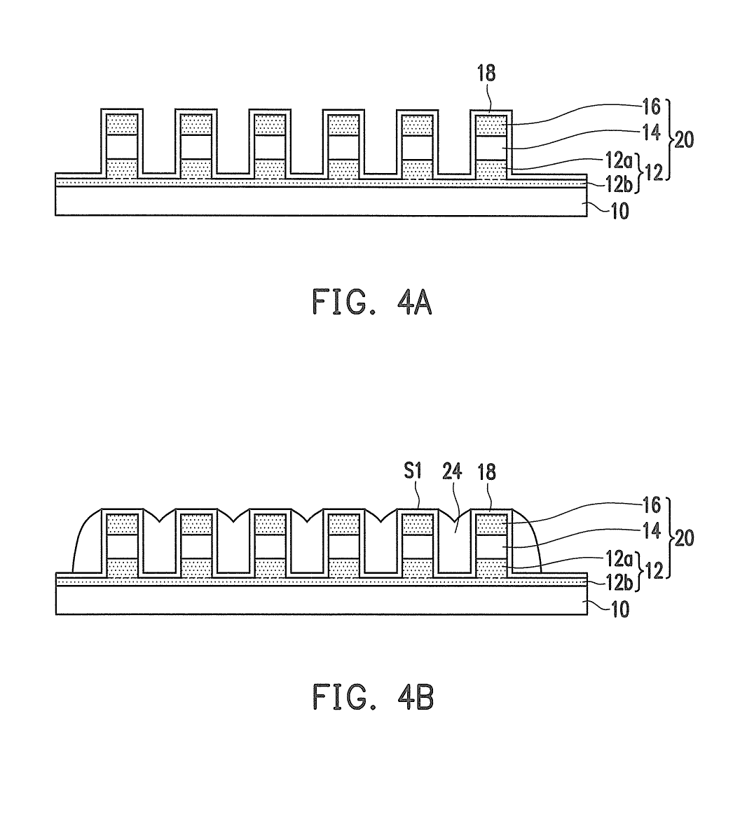

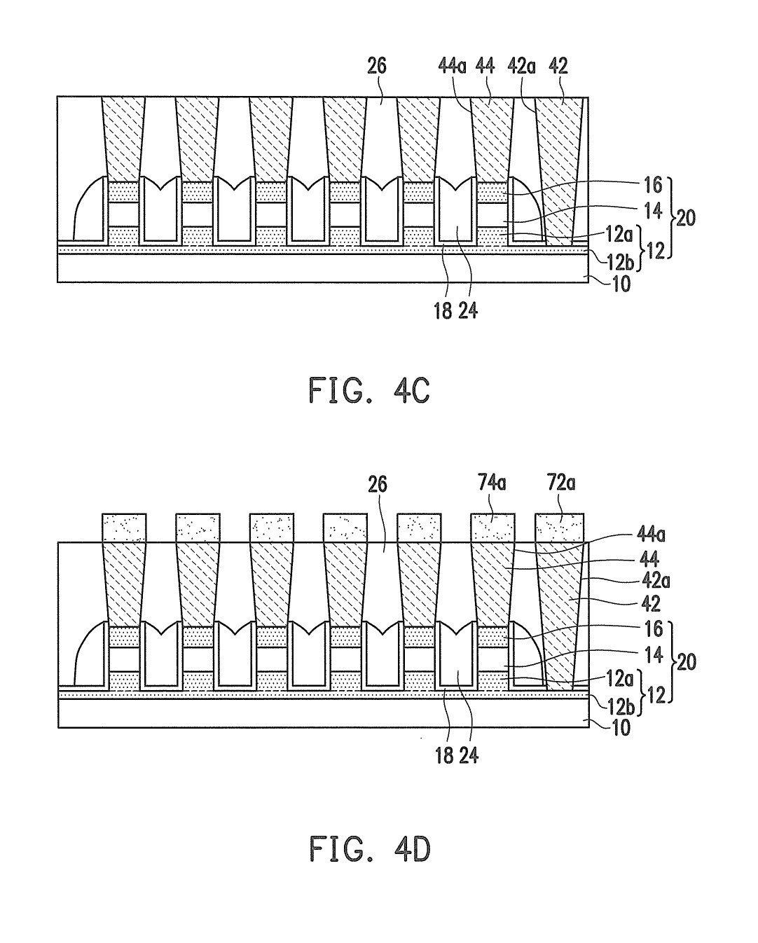

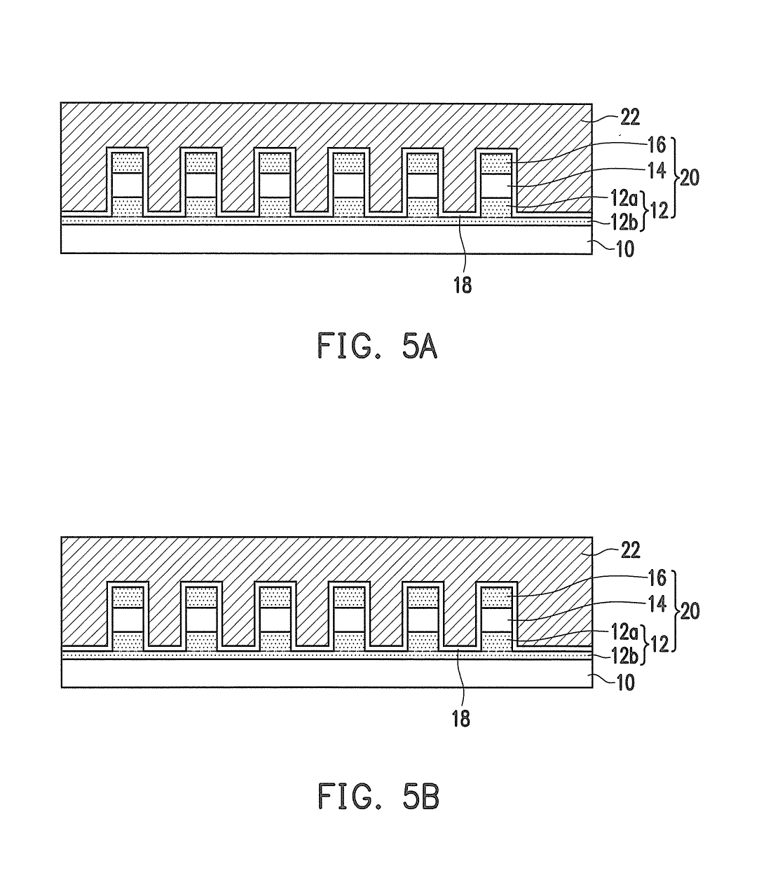

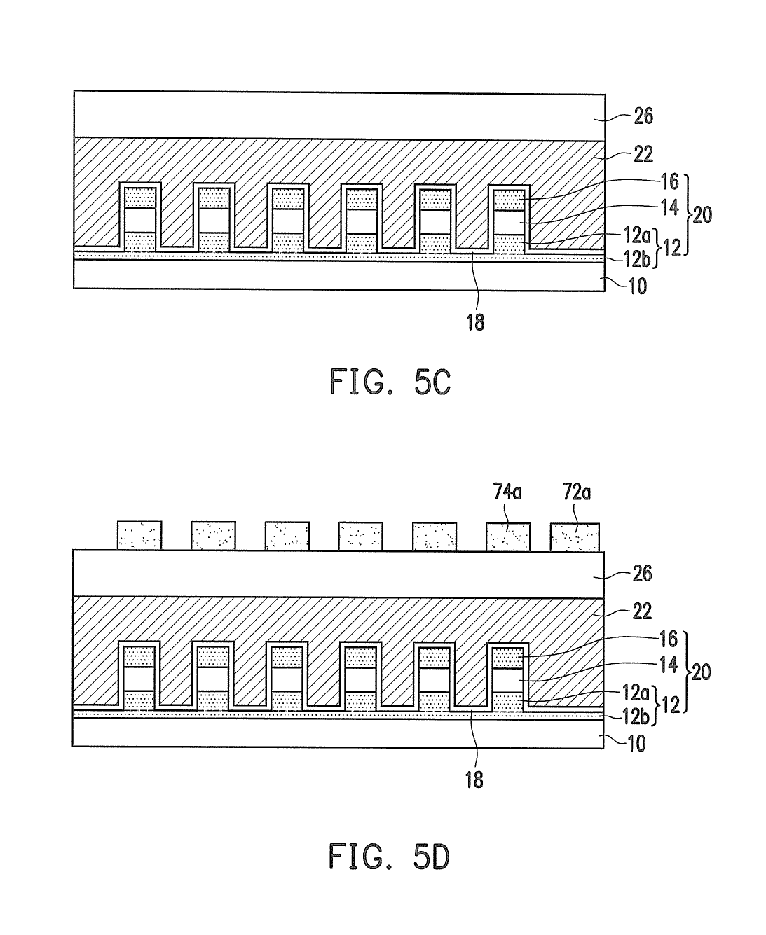

FIG. 1A to FIG. 1D are top views illustrating a fabricating method of a memory device according to the first embodiment of the invention. FIG. 2A to FIG. 2D are cross-sectional views of FIG. 1A to FIG. 1D along the line A-A′. FIG. 3A to FIG. 3D are cross-sectional views of FIG. 1A to FIG. 1D along the line B-B′. FIG. 4A to FIG. 4D are cross-sectional views of FIG. 1A to FIG. 1D along the line C-C′. FIG. 5A to FIG. 5D are cross-sectional views of FIG. 1A to FIG. 1D along the line D-D′.

With reference to FIG. 1A, FIG. 2A, FIG. 3A, FIG. 4A, and FIG. 5A, a substrate 10 is provided. The substrate 10 includes a plurality of first blocks B1 and a plurality of second blocks B2. The first blocks B1 and the second blocks B2 are alternated to each other. Each of the first blocks B1 includes two first regions R1 and a second region R2. The second region R2 is disposed between the first region R1. The substrate 10 is, for example, a semiconductor substrate, a semiconductor compound substrate, or a silicon on insulator (SOI) substrate. The substrate 10 may include an ion implantation region, which includes source/drain regions formed by P-type or N-type ion implantation, for example. The substrate 10 may include a single-layer or multi-layer structure. The substrate 10 includes a shallow trench isolation (STI) structure, for example. In an embodiment, the substrate 10 is a silicon substrate or a doped polysilicon, for example.

Next, with reference to FIG. 1A, FIG. 2A, FIG. 3A, FIG. 4A, and FIG. 5A, a plurality of semiconductor strip structures 20 are formed on the substrate 10, and a doped region 12, a body region 14, and a doped region 16 are formed in the semiconductor strip structure 20. Each of the semiconductor strip structures 20 extends along a first direction D1. The doped region 16 is located at an upper part of each of the semiconductor strip structures 20. The doped region 12 includes a plurality of first portions 12a and a second portion 12b. Each of the first portions 12a is located at a lower part of the corresponding semiconductor strip structure 20. The second portion 12b is disposed on a surface of the substrate 10, and the first portions 12a are connected with the second portion 12b. The body region 14 is disposed between the doped region 16 and the first portions 12a of the doped region 12.

The doped region 12/the body region 14/the doped region 16 serve as a source/a body/a drain, for example. The doped region 12 and the doped region 16 may be a first conductive type; and the body region 14 may be a second conductive type. The doped region 12/the body region 14/the doped region 16 are N+/P/N+ doped regions or P+/N/P+ doped regions, for example. The doped region 12 and the doped region 16 may have the same or different doping concentrations; and the body region 14 may be doped or not. In an embodiment, a doping concentration of the body region 14 is smaller than the doping concentration of the doped region 12 and the doped region 16, for example. In another embodiment, a thickness of the body region 14 is larger than a thickness of the doped region 12 and the doped region 16, for example. The thickness of the body region 14 is, for example, 30-500 nm. The thickness of the doped region 12 and the doped region 16 is, for example, 20-200 nm.

It is noted that the doped region 12 includes the first portions 12a and the second portion 12b, and the first portions 12a are connected with the second portion 12b. Therefore, the first portion 12a of the doped region 12 in each of the semiconductor strip structures 20 is connected with each other through the second portion 12b. In an embodiment, when the doped region 12 is used as the source, for example, the source in each of the semiconductor strip structures 20 is electrically connected with each other.

In an embodiment of the invention, a method of forming the semiconductor strip structure 20, the doped region 12, and the doped region 16 includes patterning a portion of the substrate 10, for example, so as to form the semiconductor strip structure 20. A patterning method includes performing a photolithographic and etching process on the substrate 10, for example. Then, a dopant is implanted into the semiconductor strip structure 20 and the substrate 10. A method of implanting the dopant includes performing an ion implantation process on the substrate 10, for example, so as to implant the dopant into the upper part of each semiconductor strip structure 20 and the surface of the substrate 10. Thereafter, a thermal annealing process is performed on the doped semiconductor strip structure 20 and the doped substrate 10, so that the dopants diffuse to form the doped region 12 and the doped region 16.

Further, with reference to FIG. 1A, FIG. 2A, FIG. 3A, FIG. 4A, and FIG. 5A, a charge storage layer 18 is formed on the substrate 10. The charge storage layer 18 is conformally formed on a top surface and a lateral surface of the semiconductor strip structure 20. Because the charge storage layer 18 is disposed on the top surface and the lateral surface of the semiconductor strip structure 20, in addition to a charge storage function, the charge storage layer 18 also provides an effect of electrically insulating the doped region 12 and the doped region 16 from a word line 22 (as shown in FIG. 5A) that is formed in a subsequent process. In an embodiment, the charge storage layer 18 is, for example, a composite layer composed of Oxide-Nitride-Oxide (ONO). The composite layer may include three layers or more. A method of forming the charge storage layer 18 includes chemical vapor deposition or thermal oxidation, for example.

Next, a word line material layer (not shown) is formed on the charge storage layer 18, and the word line material layer is conformally formed on a top surface and a lateral surface of the charge storage layer 18. A material of the word line includes N+ doped polysilicon, P+ doped polysilicon, a metal material, or a combination thereof. Then, the word line material layer is patterned to form a plurality of word lines 22 (e.g. to serve as control gates) on the substrate 10 in each first region R1. Each of the word lines 22 extends in a second direction D2 and covers a portion of a sidewall and a portion of a top of each charge storage layer 18 in the first region R1 of the substrate 10. That is, the charge storage layer 18 is disposed between the semiconductor strip structure 20 and the word line 22. The first direction D1 is different from the second direction D2. In an exemplary embodiment, the first direction D1 is substantially perpendicular to the second direction D2.

Referring to FIG. 1B, FIG. 2B, FIG. 3B, FIG. 4B, and FIG. 5B, a spacer 24 is respectively formed on each of the word lines 22 and the lateral surface of each of the semiconductor strip structures 20. More specifically, a spacer material layer (not shown) is conformally formed on the substrate 10 to cover the semiconductor strip structures 20. A material of the spacer material layer may be, for example, a silicon oxide, a silicon nitride, or a combination thereof, and a method of forming the spacer material layer may include chemical vapor deposition. Then, an anisotropic etching process is performed to remove a portion of the spacer material layer and a portion of the charge storage layer 18, so as to form the spacer 24 on each of the word lines 22 and the later surface of each of the semiconductor strip structures 20 respectively. In an embodiment, the spacer 24 exposes a top surface S1 (as shown in FIG. 4B) of the charge storage layer 18 on each of the semiconductor strip structures 20. In another embodiment, in order to ensure that the spacer material layer on the top surface S1 of the charge storage layer 18 is completely removed, an over etching may be included in the etching process, such that a portion of the charge storage layer 18 can be removed. Therefore, the spacer 24 exposes a top surface S2 of the semiconductor strip structure 16 (as shown in FIG. 2B).

Referring to FIG. 1C, FIG. 2C, FIG. 3C, FIG. 4C, and FIG. 5C, a dielectric layer 26 is formed on the substrate 10. Next, a photolithographic and etching process is performed to remove a portion of the dielectric layer 26 and a portion of the charge storage layer 18, so as to form a plurality of first contact openings 42a in the second blocks B2 and the second regions R2 of the substrate 10 and form a plurality of second contact openings 44a at least in the second regions R2. Each of the first contact openings 42a exposes the second portion 12b of the doped region 12. Each of the second contact openings 44a exposes the doped region 16 of the semiconductor strip structure 20.

Thereafter, first contacts 42 and second contacts 44 are formed in the first contact openings 42a and the second contact openings 44a respectively. The first contacts 42 are respectively disposed in the second blocks B2 and the second regions R2 and arranged along the first direction D1; and the second contacts 44 are at least disposed in the second regions R2. In an exemplary embodiment, the first contacts 42 are disposed in the second blocks B2 and the second regions R2 at a side of the outermost semiconductor strip structures 20 on a portion of the substrate 10. The second contacts 44 are disposed in the second regions R2 and the second blocks B2. Each of the first contacts 42 is electrically connected with the second portion 12b of the doped region 12. Each of the second contacts 44 is electrically connected with the doped region 16 of the corresponding semiconductor strip structure 20. A method of forming the first contacts 42 and the second contacts 44 includes forming a conductor material layer on the substrate 10 first, for example. The conductor material layer is aluminum, copper, or an alloy thereof, for example. The forming method of the conductor material layer may be physical vapor deposition, such as sputtering. Thereafter, the conductor material layer outside the first contact openings 42a and the second contact openings 44a is removed by chemical mechanical polishing or etching back.

Referring to FIG. 1D, FIG. 2D, FIG. 3D, FIG. 4D, and FIG. 5D, a conductor material layer (not shown) is formed on the substrate 10. Then, the conductor material layer is patterned by a photolithographic and etching process to form a first conductive line 72a and a plurality of second conductive lines 74a. The first conductive line 72a extends in the first direction D1 and is electrically connected with the first contact 42. The second conductive line 74a extends in the first direction D1 and is electrically connected with the second contact 44 on the corresponding semiconductor strip structure 20. The first conductive line 72a is a source line and the second conductive lines 74a are bit lines, for example. A material of the conductor material layer may be, for example, a doped polysilicon, an undoped polysilicon, or a combination thereof, and a forming method thereof may include chemical vapor deposition.

Referring to FIG. 1D to FIG. 5D, according to the first embodiment of the invention, a memory device 100 includes the substrate 10, a plurality of semiconductor strip structures 20, the doped region 12, a plurality of body regions 14, a plurality of doped regions 16, a plurality of word lines 22, the charge storage layer 18, a plurality of first contacts 42, a plurality of second contacts 44, the first conductive line 72a, and a plurality of second conductive lines 74a. The doped region 12 includes a plurality of first portions 12a and the second portion 12b, and the first portions 12a are connected with the second portion 12b. Moreover, the second portion 12b of the doped region 12 may be electrically connected with the first conductive line 72a through the first contacts 42. The doped regions 16 may be electrically connected with the second conductive lines 74a through the second contacts 44.

It is noted that the first portions 12a and the second portion 12b of the doped region 12 are connected with each other, and thus the first portion 12a of the doped region 12 of each of the semiconductor strip structures 20 is connected with one another. That is to say, when the doped region 12 is used as a source of the memory device, for example, a source in each of the semiconductor strip structures 20 is electrically connected with each other. Further, because the first contacts 42 are electrically connected with the second portion 12b of the doped region 12, the first conductive line 72a is electrically connected the source in each of the semiconductor strip structures 20, for example. Accordingly, the relative relationship between vertical memory devices and the configuration of the stack structure can be significantly simplified without sacrificing the operational performance and the compatibility with the current fabricating processes.

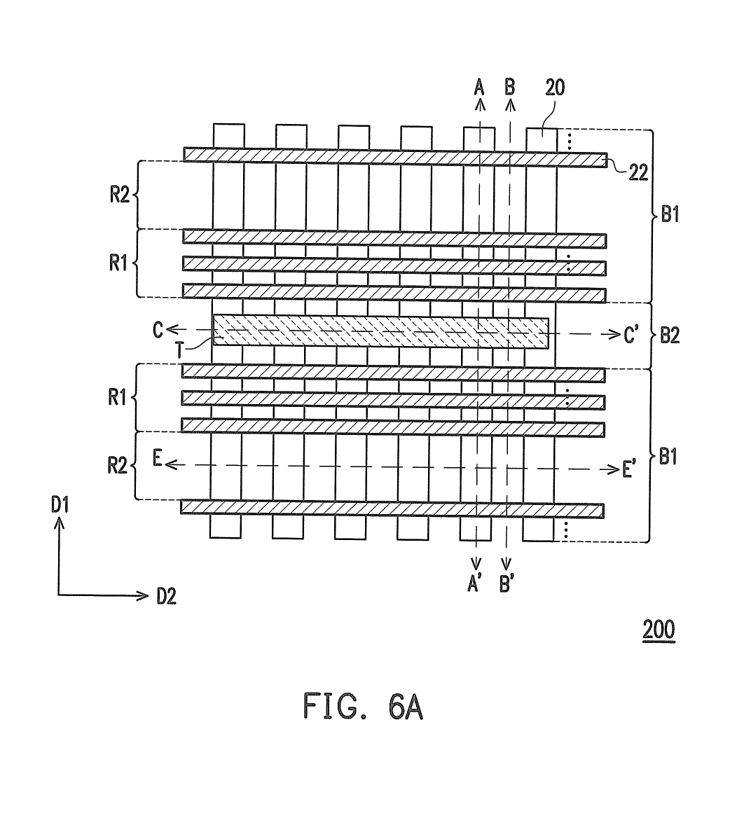

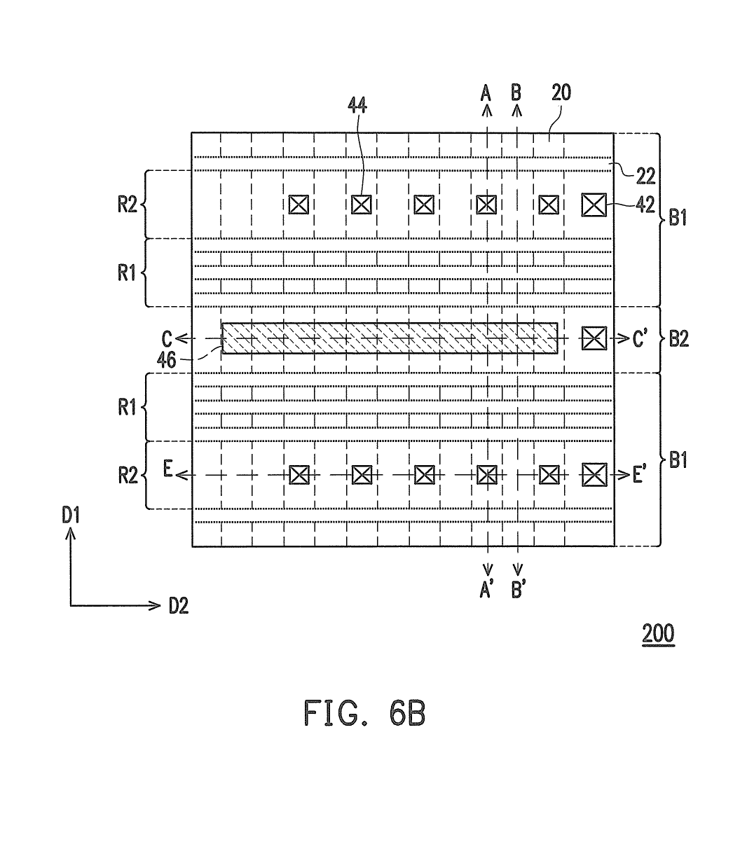

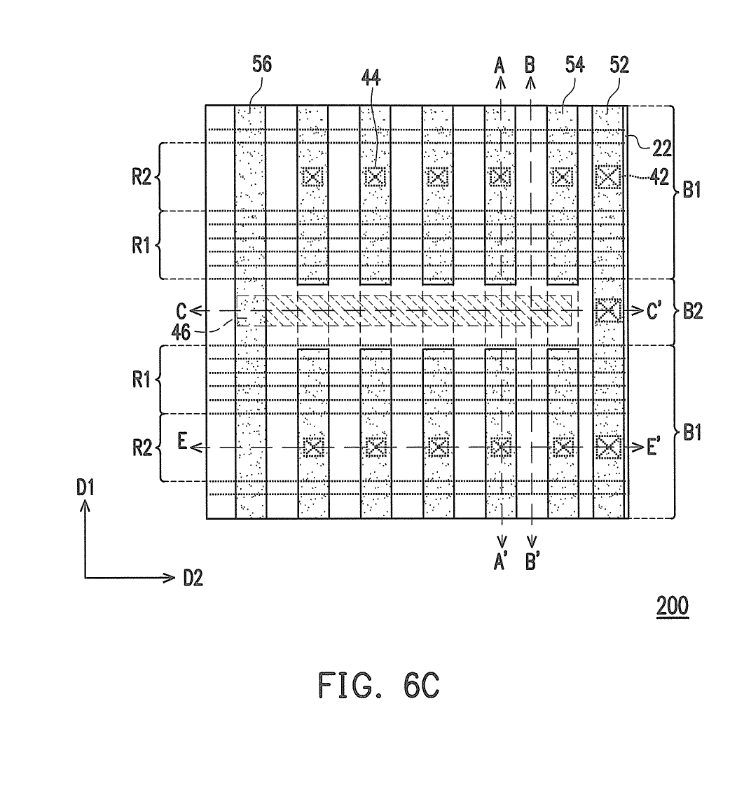

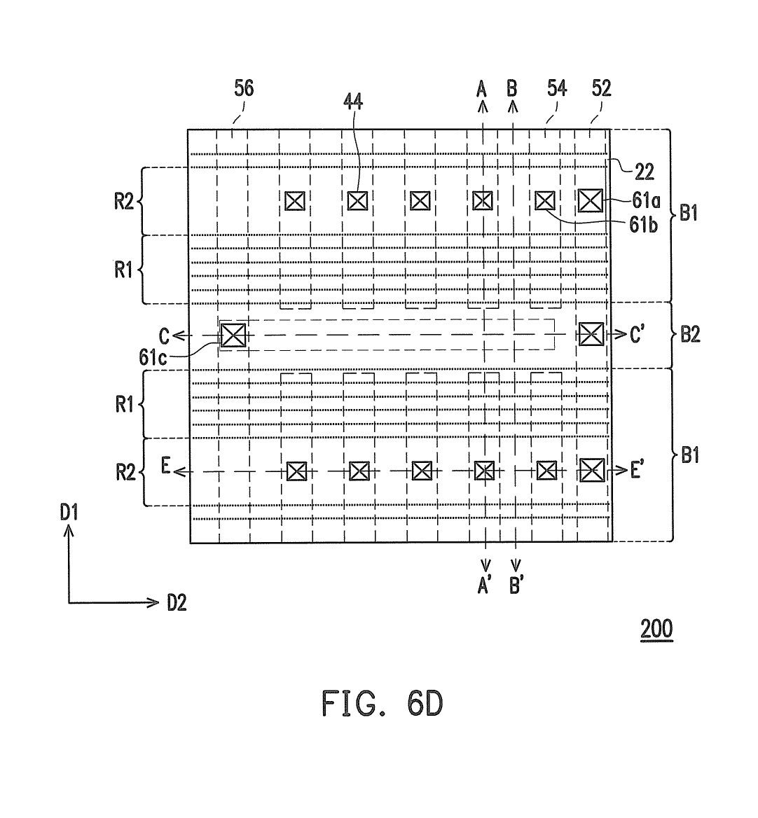

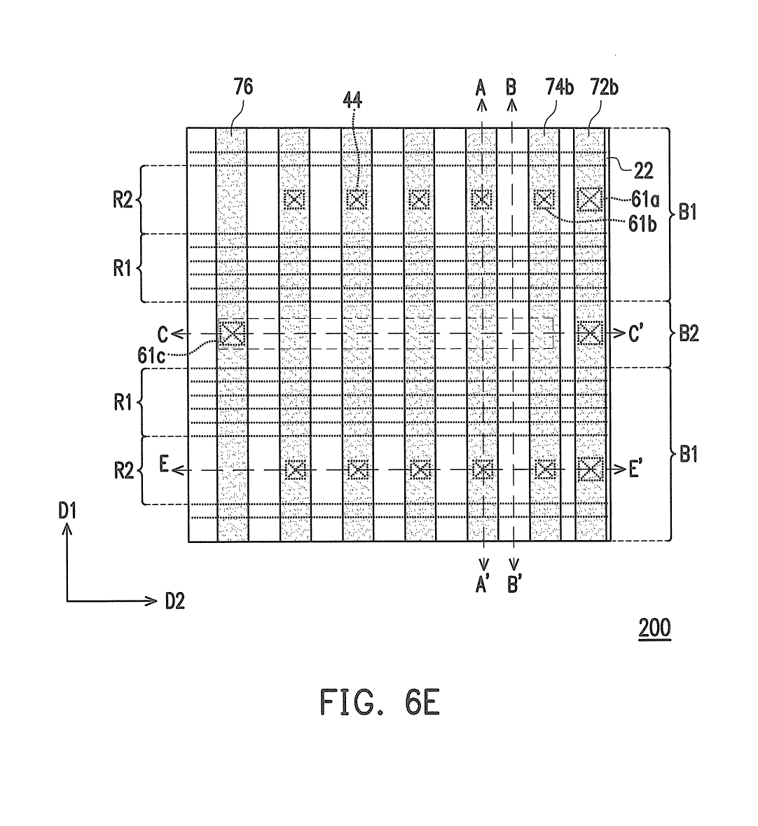

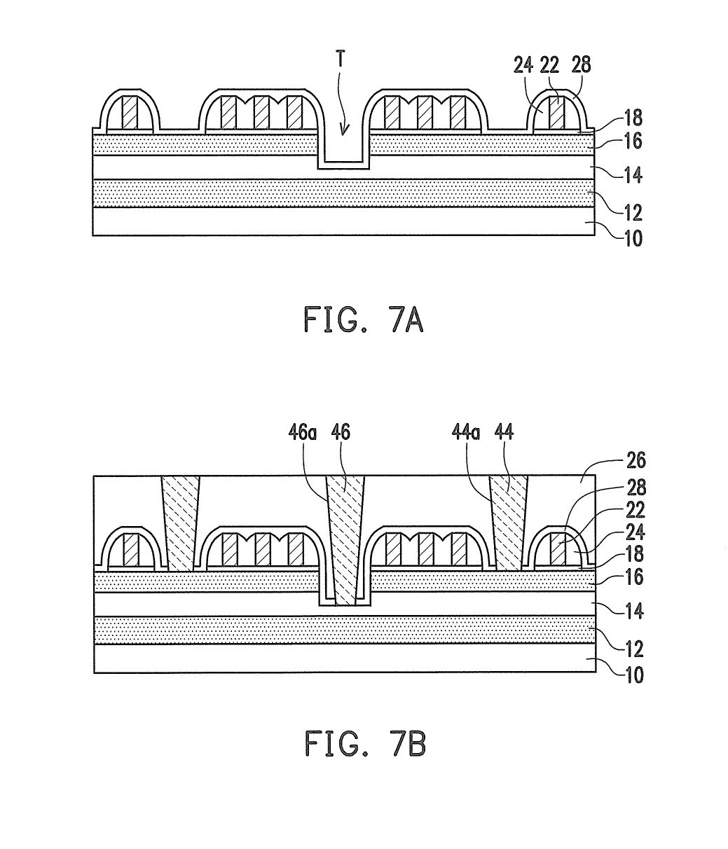

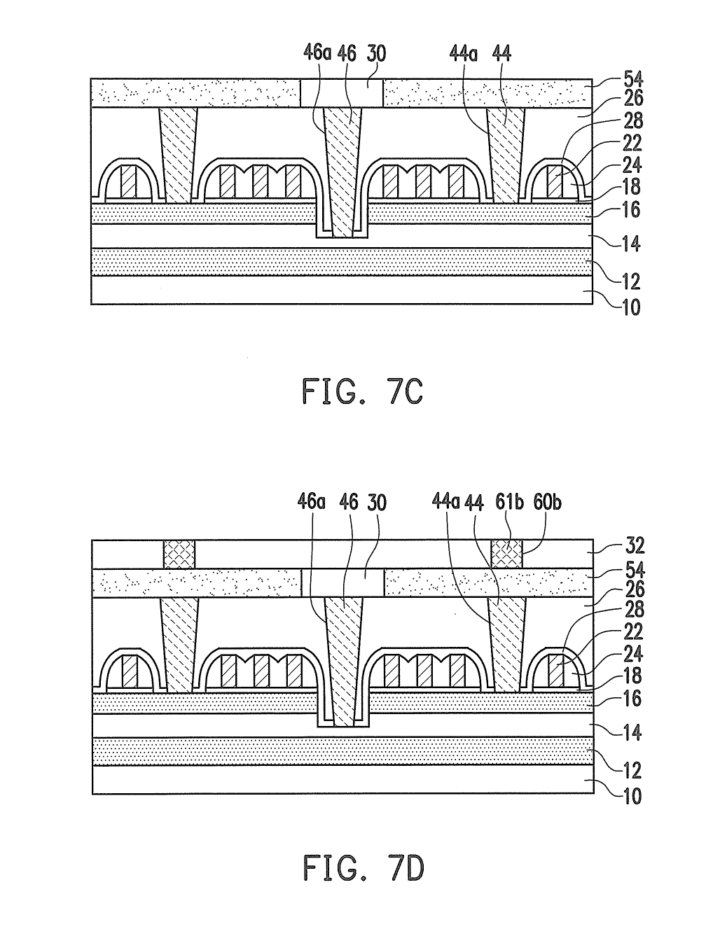

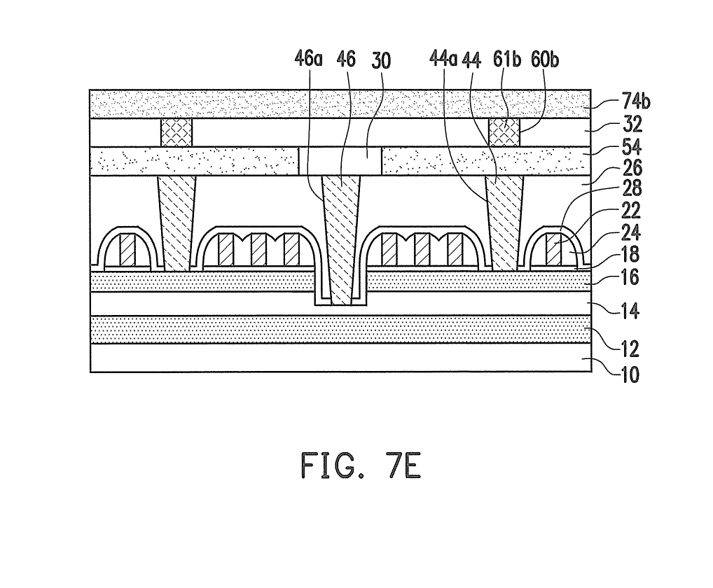

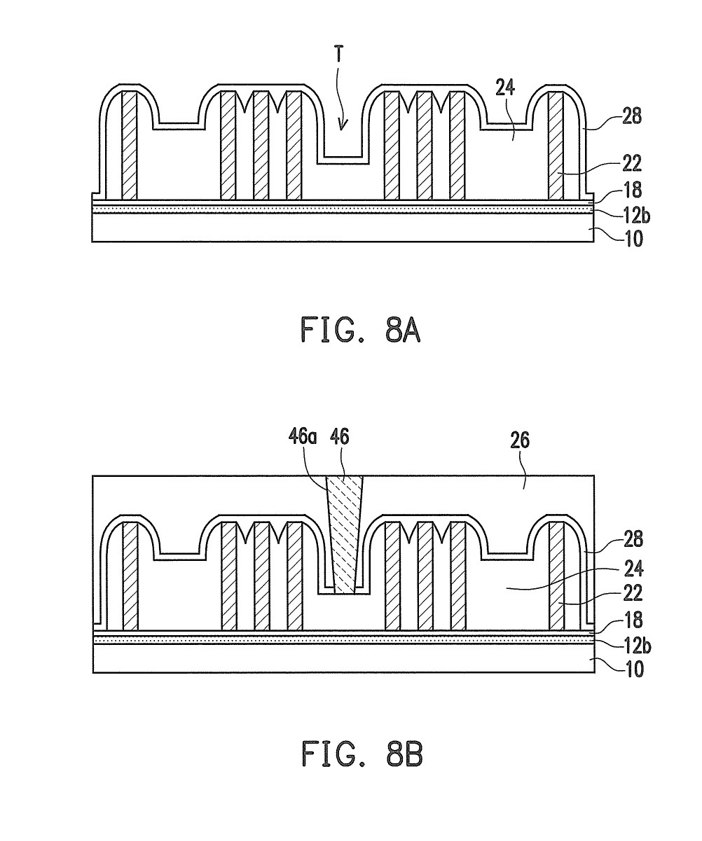

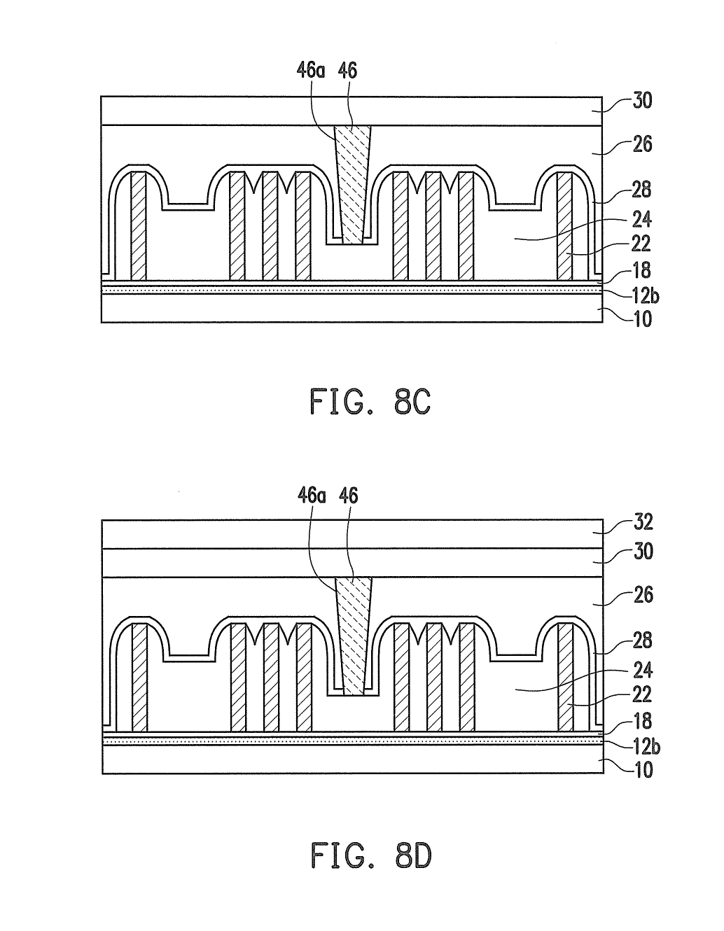

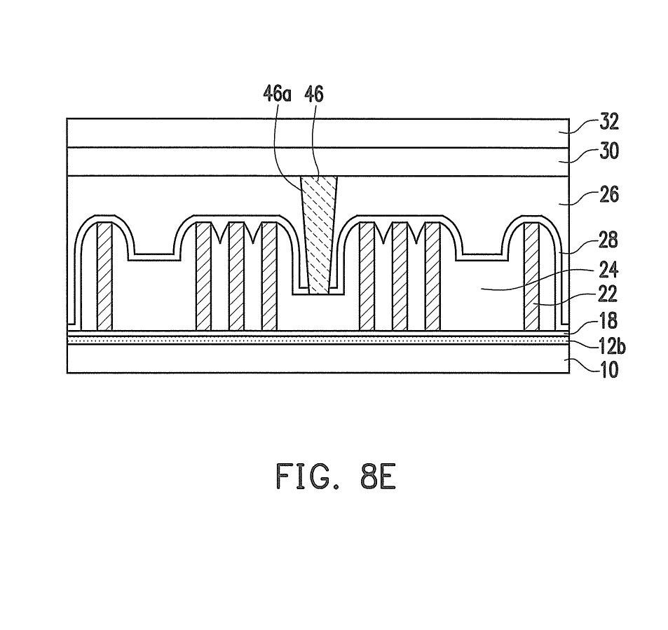

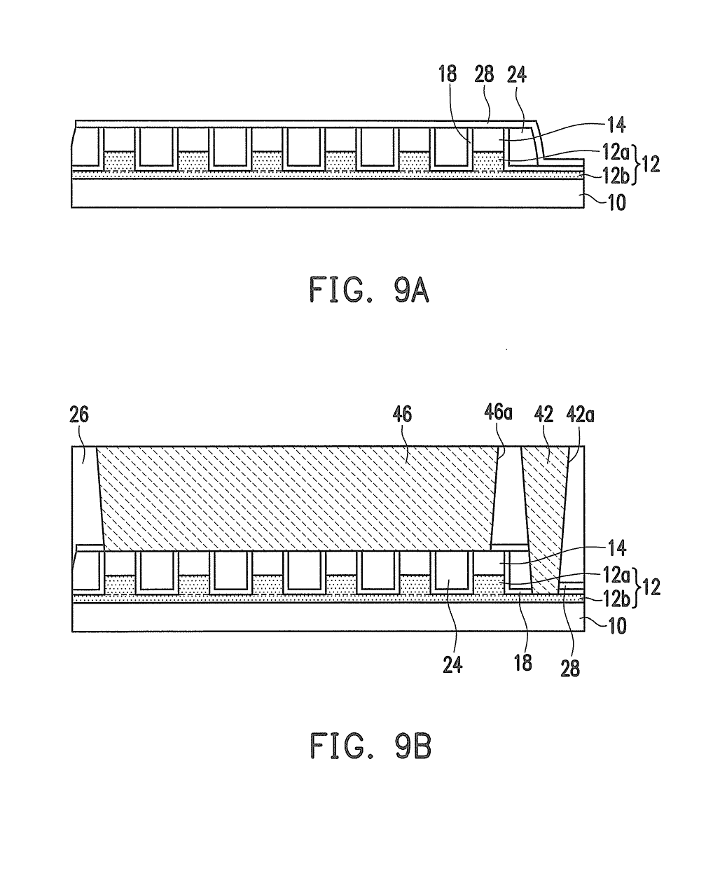

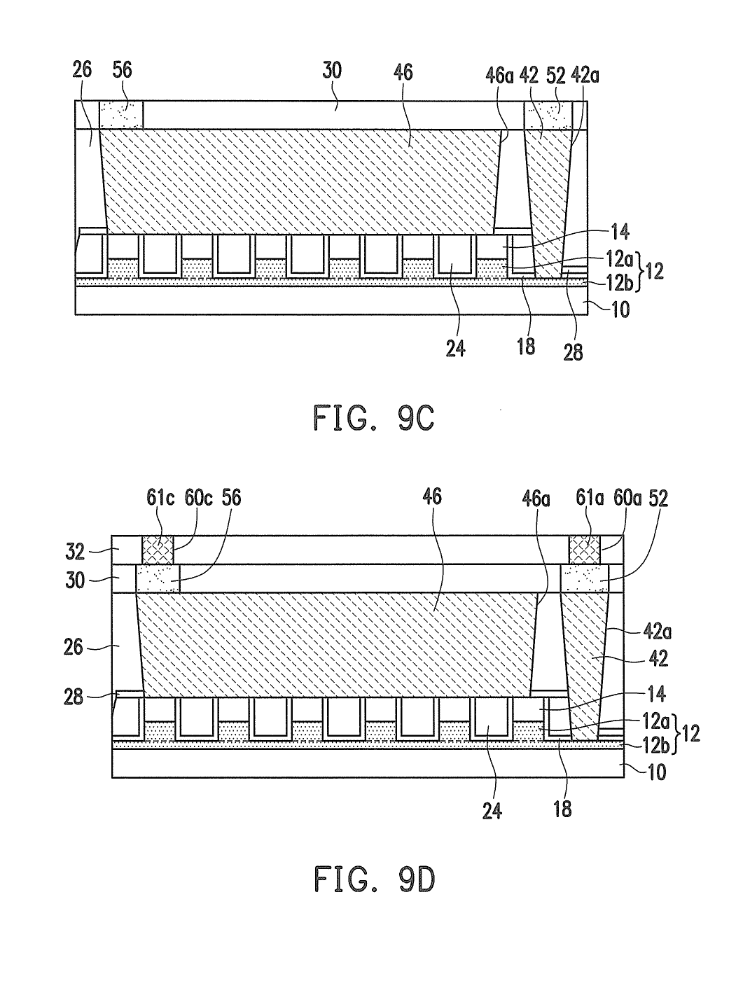

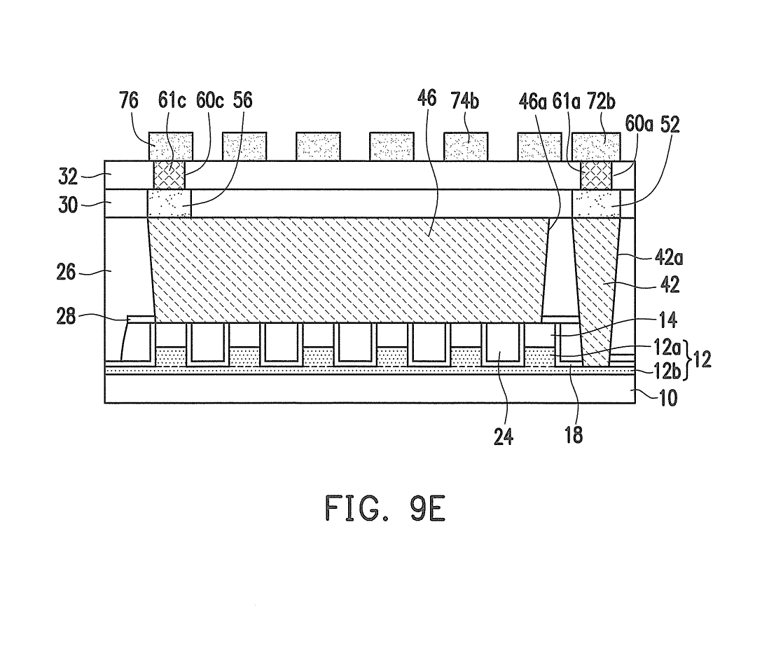

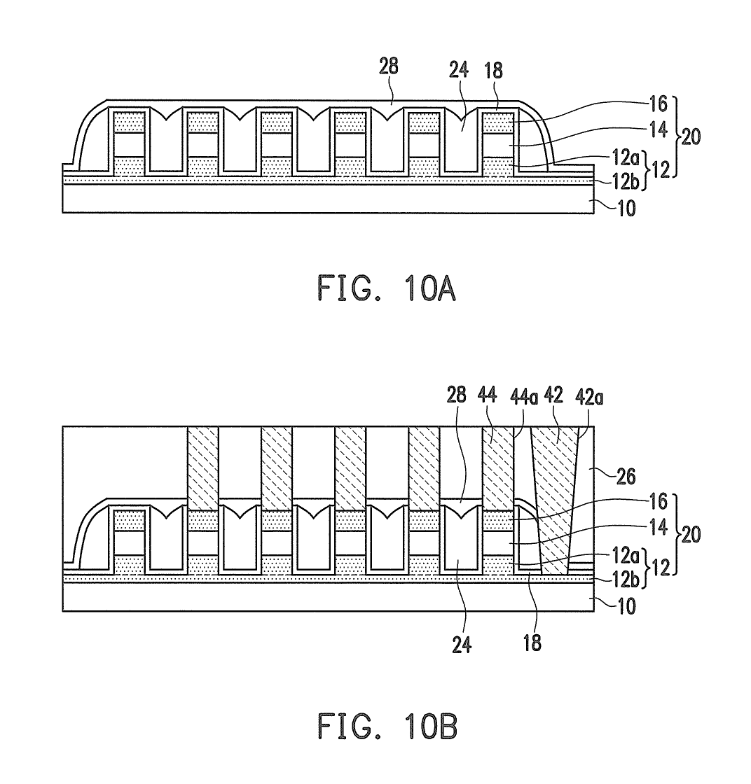

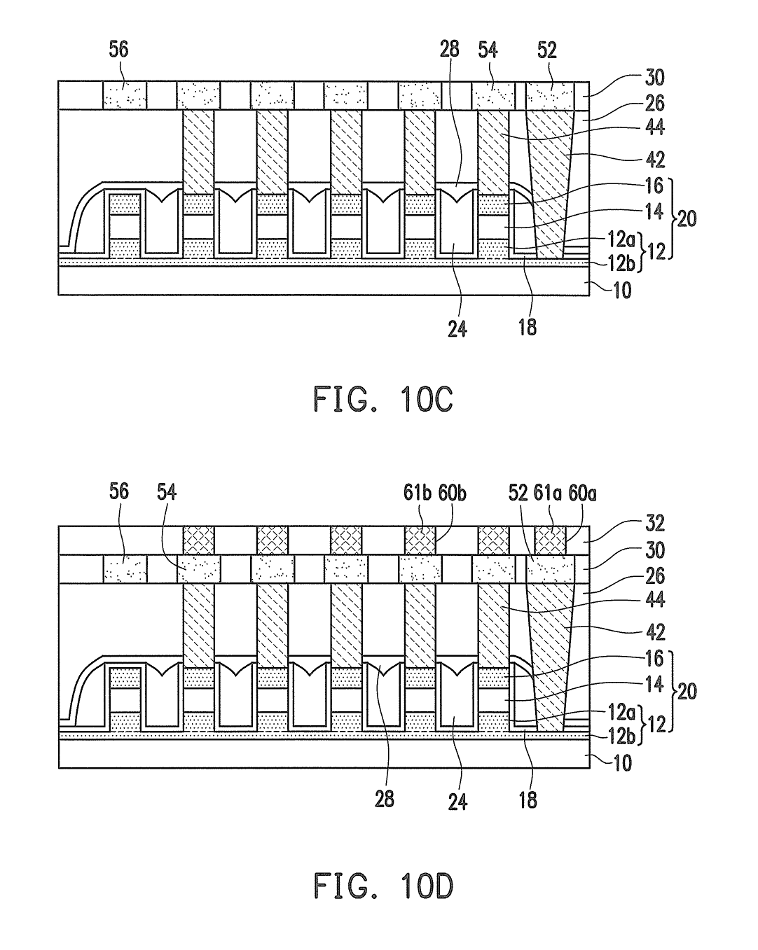

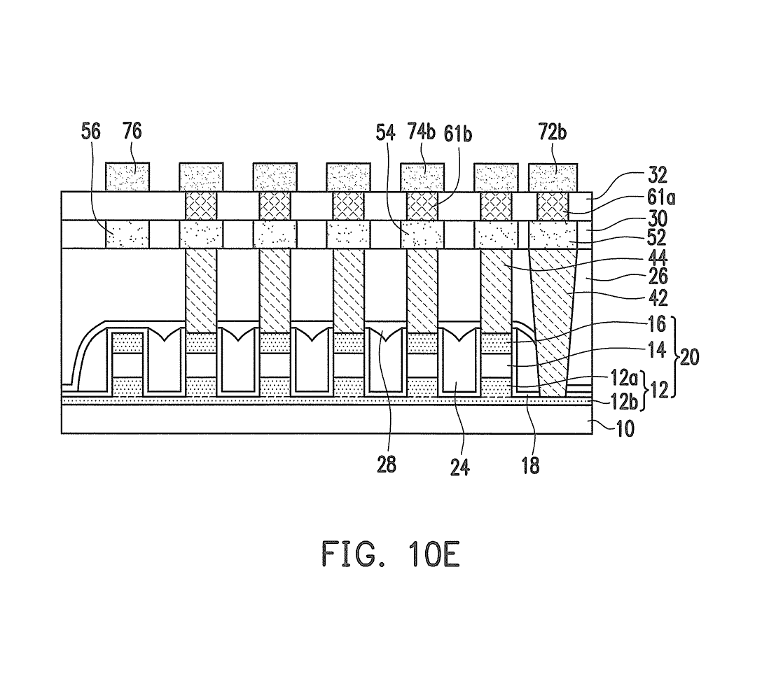

FIG. 6A to FIG. 6E are top views illustrating a fabricating process of a memory device according to the second embodiment of the invention. FIG. 7A to FIG. 7E are cross-sectional views of FIG. 6A to FIG. 6E along the line A-A′. FIG. 8A to FIG. 8E are cross-sectional views of FIG. 6A to FIG. 6E along the line B-B′. FIG. 9A to FIG. 9E are cross-sectional views of FIG. 6A to FIG. 6E along the line C-C′. FIG. 10A to FIG. 10E are cross-sectional views of FIG. 6A to FIG. 6E along the line E-E′.

Part of the fabricating processes of a memory device 200 of the second embodiment may be the same as those of the memory device 100 of the first embodiment. More specifically, the fabricating processes of the substrate 10, the semiconductor strip structures 20, the doped region 12, the body regions 14, the doped regions 16, the word lines 22, the charge storage layer 18, and the spacer 24 in the memory device 200 may be the same as those for the memory device 100. Thus, details thereof are not repeated hereinafter.

Referring to FIG. 6A, FIG. 7A, FIG. 8A, FIG. 9A, and FIG. 10A, after forming the spacer 24 respectively on each of the word lines 22 and the lateral surface of each of the semiconductor strip structures 20, a portion of the semiconductor strip structure 20 in the second blocks B2 of the substrate 10 is removed to form a trench T (as shown in FIG. 6A, FIG. 7A, and FIG. 8A). The trench T extends along the second direction D2, for example. The trench T exposes the body region 14 (not shown) of the corresponding semiconductor strip structure 20. In this embodiment, each of the semiconductor strip structures 20 has the body region 14. In the first blocks B1, each of the body region 14 is disposed between the doped region 16 and the first portion 12a of the doped region 12; and in the second blocks B2, each of the body region 14 is disposed on the first portion 12a of the doped region 12, and the trench T exposes the body region 14. Next, a liner layer 28 is conformally formed on the substrate 10 to cover the semiconductor strip structures 20 and the word lines 22. A material of the liner layer 28 is, for example, a silicon oxide, a silicon oxynitride, a silicon nitride, or a combination thereof. The liner layer 28 may be formed by chemical vapor deposition or physical vapor deposition.

Referring to FIG. 6B, FIG. 7B, FIG. 8B, FIG. 9B, and FIG. 10B, the dielectric layer 26 is formed on the substrate 10. Then, a photolithographic and etching process is performed to remove a portion of the dielectric layer 26 and a portion of the liner layer 28, so as to form a plurality of first contact openings 42a in the second blocks B2 and the second regions R2 of the substrate 10, form a plurality of second contact openings 44a in the second regions R2, and form a plurality of third contact openings 46a in the second blocks B2. Each of the first contact openings 42a exposes the second portion 12b of the doped region 12. Each of the second contact openings 44a exposes the doped region 16 of the semiconductor strip structure 20. Each of the third contact openings 46a exposes the body regions 14 of the semiconductor strip structures 20.

Thereafter, the first contacts 42, the second contacts 44, and third contacts 46 are respectively formed in the first contact openings 42a, the second contact openings 44a, and the third contact openings 46a. The first contacts 42 are disposed in the second blocks B2 and the second regions R2 and arranged along the first direction D1; the second contacts 44 are disposed in the second regions R2 and arranged along the second direction D2; and the third contacts 46 are disposed in the second blocks B2 and arranged along the second direction D2. In an exemplary embodiment, the first contacts 42 are disposed in the second blocks B2 and the second regions R2 at a side of the outermost semiconductor strip structures 20 on a portion of the substrate 10. Each of the first contacts 42 is electrically connected with the second portion 12b of the doped region 12. Each of the second contacts 44 is electrically connected with the doped region 16 of the corresponding semiconductor strip structure 20. Each of the third contacts 46 is electrically connected with the body region 14 exposed by the trench T. The forming method of the first contacts 42, the second contacts 44, and the third contacts 46 is the same as that for forming the first contacts 42 and the second contacts 44 in the first embodiment. Thus, details thereof are not repeated hereinafter.

Referring to FIG. 6C, FIG. 7C, FIG. 8C, FIG. 9C, and FIG. 10C, a conductor material layer (not shown) is formed on the substrate 10. Then, the conductor material layer is patterned by a photolithographic and etching process to form a fourth conductive line 52, a plurality of local conductive lines 54, and a fifth conductive line 56. In an embodiment, the local conductive lines 54 are disposed in the first blocks B1 at two sides of the third contacts 46. The fourth conductive line 52 extends in the first direction D1 and is electrically connected with the first contacts 42. Each of the local conductive lines 54 extends in the first direction D1 and is electrically connected with the second contact 44 on the corresponding semiconductor strip structure 20. The fifth conductive line 56 extends in the first direction D1 and is electrically connected with the third contacts 46. The material and forming method of the conductor material layer are the same as the first embodiment. Thus, details thereof are not repeated hereinafter. Next, a dielectric layer 30 is formed on the substrate 10. The dielectric layer 30 electrically insulates the fourth conductive line 52, the local conductive lines 54, and the fifth conductive line 56 from each other respectively. The material and forming method of the dielectric layer 30 have been specified above. Thus, details thereof are not repeated hereinafter.

Referring to FIG. 6D, FIG. 7D, FIG. 8D, FIG. 9D, and FIG. 10D, a dielectric layer 32 is formed on the substrate 10. Next, a photolithographic and etching process is performed to remove a portion of the dielectric layer 32, so as to form a plurality of fourth contact openings 60a, a plurality of fifth contact openings 60b, and a sixth contact opening 60c in the substrate 10. The fourth contact openings 60a expose the fourth conductive line 52, the fifth contact openings 60b expose the local conductive lines 54, and the sixth contact opening 60c exposes the fifth conductive line 56. Thereafter, fourth contacts 61a are formed in the fourth contact openings 60a, fifth contacts 61b are formed in the fifth contact openings 60b, and a sixth contact 61c is formed in the sixth contact opening 60c.

Referring to FIG. 6E, FIG. 7E, FIG. 8E, FIG. 9E, and FIG. 10E, a conductor material layer (not shown) is formed on the substrate 10. Then, the conductor material layer is patterned to form a first conductive line 72b, a plurality of second conductive lines 74b, and a third conductive line 76. The first conductive line 72b extends in the first direction D1 and is electrically connected with the first contacts 42 through the fourth contacts 61a and the fourth conductive line 52. The second conductive lines 74b extend in the first direction D1 and are disposed on the local conductive lines 54 on the corresponding semiconductor strip structure 20. In addition, the second conductive lines 74b span across the third contacts 46 and are electrically connected with the corresponding local conductive lines 54 through the fifth contacts 61b. The third conductive line 76 extends in the first direction D1 and is electrically connected with the third contacts 46 through the sixth contact 61c and the fifth conductive line 56. The first conductive line 72b, the second conductive lines 74b, and the third conductive line 76 are a source line, bit lines, and a body line respectively, for example. The material and forming method of the conductor material layer have been specified above. Thus, details thereof are not repeated hereinafter.

Referring to FIG. 1D, FIG. 4D, and FIG. 5D, the memory device of the first embodiment of the invention includes: the substrate 10, a plurality of semiconductor strip structures 20, a first doped region 12, a plurality of second doped regions 16, a plurality of word lines 22, the charge storage layer 18, a plurality of first contacts 42, a plurality of second contacts 44, the first conductive line 72, and a plurality of second conductive lines 74.

With reference to FIG. 1D, the substrate 10 includes two first blocks B1 and the second blocks B2. The second blocks B2 are disposed between the two first blocks B1, wherein each of the first blocks B1 includes a plurality of first regions R1 and a plurality of second regions R2, and the first regions R1 and the second regions R2 are alternated to each other.

With reference to FIG. 4D, the semiconductor strip structures 20 are disposed on the substrate 10. Each of the semiconductor strip structures 20 extends along the first direction D1. The first doped region 12 includes a plurality of first portions 12a and the second portion 12b. Each of the first portions 12a is disposed at the lower part of the corresponding semiconductor strip structure 20; and the second portion 12b is disposed on the surface of the substrate 10, and the first portions 12a are connected with the second portion 12b. The second doped regions 16 are disposed at the upper part of each of the semiconductor strip structures 20.

With reference to FIG. 1D and FIG. 5D, a plurality of word lines 22 are disposed on the substrate 10 in each of the first regions R1. Each of the word lines 22 extends in the second direction D2 and covers a portion of the sidewall and a portion of the top of each of the semiconductor strip structures 20. The first direction D1 is different from the second direction D2. The charge storage layer 18 is disposed between the semiconductor strip structure 20 and the word line 22.

With reference to FIG. 1D and FIG. 4D, the first contacts 42 are disposed in the second blocks B2 and the second regions R2 and arranged along the first direction D1. Each of the first contacts 42 is electrically connected with the second portion 12b of the first doped region 12. The second contacts 44 are disposed at least in the second regions R2, and each of the second contacts 44 is electrically connected with the corresponding second doped region 16. The first conductive line 72a is disposed on the substrate 10 and extends in the first direction D1, and is electrically connected with the first contacts 42. A plurality of second conductive lines 74a are disposed on the substrate 10. Each of the second conductive lines 74a extends in the first direction D1 and is electrically connected with the second contact 44 on the corresponding semiconductor strip structure 20.

It is noted that the doped region 12 includes the first portions 12a and the second portion 12b, and the first portions 12a are connected with the second portion 12b. Therefore, the first portion 12a of the doped region 12 in each of the semiconductor strip structures 20 is connected with each other through the second portion 12b. In an embodiment, when the doped region 12 is used as the source, for example, the source in each of the semiconductor strip structures 20 is electrically connected with each other.

Further, with reference to FIG. 6A, FIG. 9A, and FIG. 10A, compared with the memory device 100 of the first embodiment, the memory device 200 provided in the second embodiment of the invention includes the trench T in the second blocks B2, and the trench T extends in the second direction to expose the body region 14. In other words, in the first blocks B1, each of the body region 14 is disposed between the doped region 14 and the first portion 12a of the doped region 12; and in the second blocks B2, each of the body region 14 is disposed on the first portion 12a of the doped region 12, and the trench T exposes the body region 14.

In addition, the memory device 200 of the second embodiment further includes: the third contacts 46, the fourth conductive line 52, a plurality of local conductive lines 54, the fifth conductive line 56, the fourth contact 61a, the fifth contact 61b, the sixth contact 61c, and the third conductive line 76.

With reference to FIG. 6E and FIG. 9E, the third contacts 46 are disposed in the second blocks B2 of the substrate 10 and extends in the second direction D2, and each of the third contacts 46 is electrically connected with the body regions 14 of a portion of the semiconductor strip structures 20. The third conductive line 76 is disposed on the substrate 10 and extends in the first direction D1, and the third conductive line 76 is electrically connected with the body region 14 of the semiconductor strip structure 20 through the sixth contact 61c, the fifth conductive line 56, and the third contacts 46. Thus, when the body region 14 is used as a body of the memory device, for example, a voltage can be applied to the body through the third conductive line 76 for controlling a potential of the body. Accordingly, the potential of the body can be obtained to prevent the potential of the body from becoming a floating state due to a coupling effect of other bias.

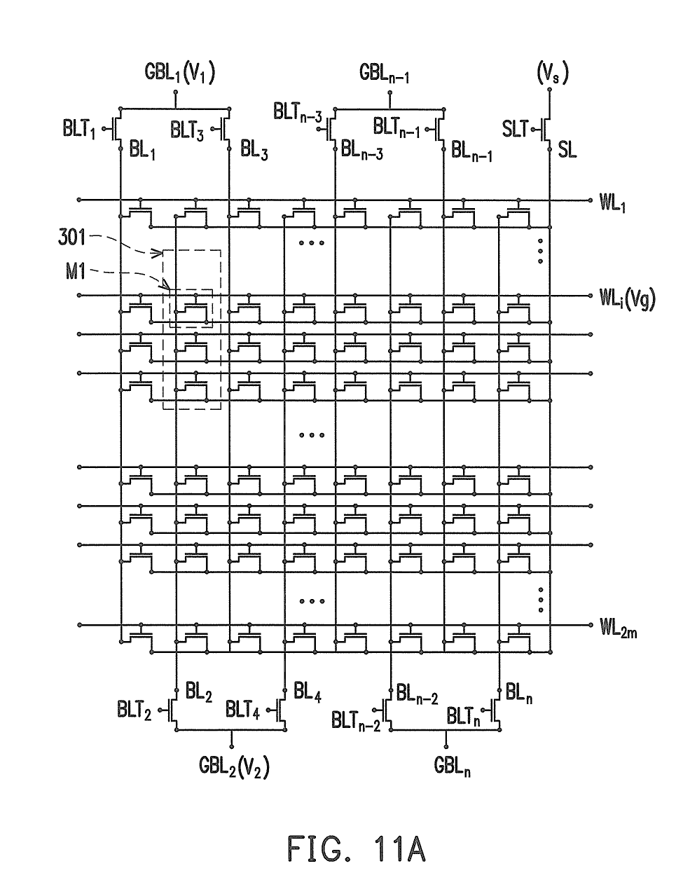

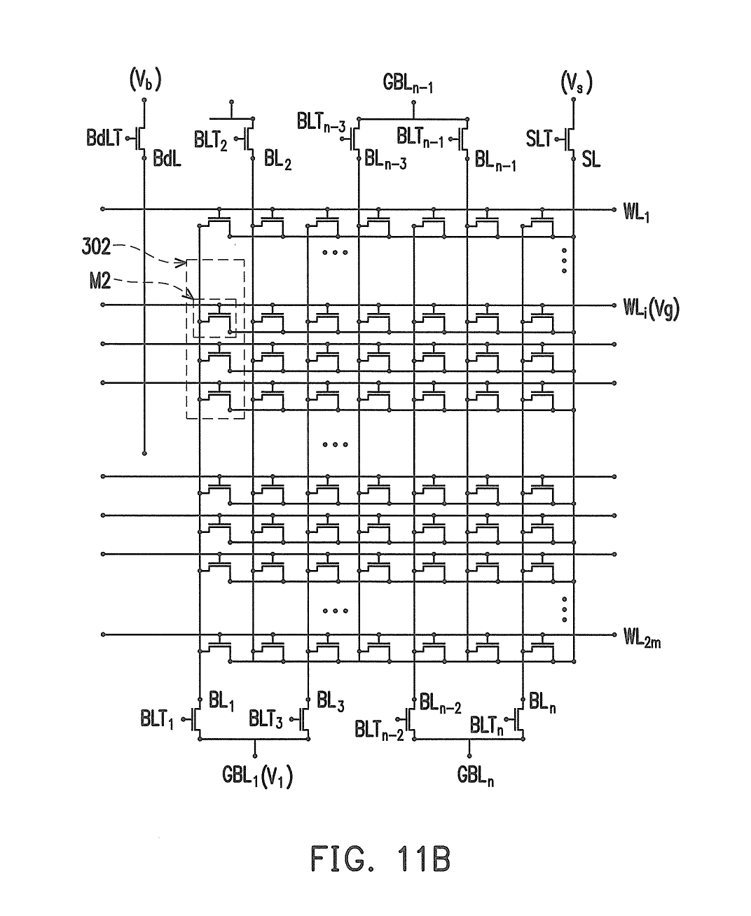

FIG. 11A is a schematic view illustrating a memory array structure according to the first embodiment of the invention.

With reference to FIG. 11A, FIG. 11A illustrates a plurality of cell strings 301. The cell strings 301 are connected in series through a plurality of bit lines BL₁ to BLₙ (wherein n is an integer greater than 1), a source line SL, and a plurality of word lines WL₁ to WL₂ₘ (wherein m is an integer greater than 1), and are arranged in a memory array in a row direction and a column direction. Each of the first regions R1 (e.g. the first region R1 of FIG. 1D) is formed by arranging the cell strings 301 in parallel. In an embodiment, each of the cell strings 301 may include 32 memory cells or more memory cells.

The source line SL may be coupled to the first conductive line 72a (as shown in FIG. 4D) to connect a source (e.g. the doped region 12 of FIG. 4D; at the moment, the doped region 12 serves as a common source line, for example) of each memory cell in the memory array in series. The bit lines BL₁, BL₂, . . . BLₙ may be respectively coupled to the second conductive lines 74a (as shown in FIG. 4D), so as to respectively connect drains (e.g. the doped regions 16 of FIG. 4D) of the memory cells of the same column in the memory array in series. The word lines WL₁, WL₂, . . . WL₂ₘ may respectively connect gates of the memory cells of the same row in the memory array in series. In an embodiment, the bit lines BL₁, BL₂, . . . BLₙ may be respectively coupled to bit line transistors BLT₁, BLT₂, . . . BLTₙ. The bit lines BL₁ and BL₃ may be coupled to a global bit line GBL₁. The bit lines BL₂ and BL₄ may be coupled to a global bit line GBL₂. A control voltage V₁ is applied, through the global bit line GBL₁, to the bit lines BL₁ and BL₃ by turning the bit line transistors BLT₁ and BLT₃ on/off.

In an embodiment of the invention, different voltages may be respectively applied to a source, a drain, and a gate corresponding to a memory cell M1 so as to perform an operation of reading, programming, or erasing. For instance, a method of performing the reading operation on the memory cell M1 includes: applying a 10V voltage to turn on the bit line transistor BLT₂, such that through the bit line transistor BLT₂ and the bit line BL₂, a control voltage V₂ (e.g. V₂=0V) applied to the global bit line GBL₂ may be provided to the drain of the memory cell M1 to serve as a drain voltage V_{d}; applying a 10V voltage to turn on a source line transistor SLT, such that a control voltage of 1.6V may be provided, through the source line SL, to the source of the memory cell M1 to serve as a source voltage Vₛ; and applying a voltage of 0V to 10V to a word line WLᵢ connected to the gate of the memory cell M1 to serve as a gate voltage V_{g}. Accordingly, the operation of reading the memory cell M1 is performed. It should be noted that the scope of the invention is not limited to the voltages specified above. In another embodiment, the voltages of the source, drain, and gate corresponding to the memory cell M1 may be adjusted to perform the programming or erasing operation.

FIG. 11B is a schematic view illustrating a memory array structure according to the second embodiment of the invention.

With reference to FIG. 11B, FIG. 11B illustrates a plurality of cell strings 302. The cell strings 302 are connected in series through a body line BdL, a plurality of bit lines BL₁ to BLₙ (wherein n is an integer greater than 1), the source line SL, and a plurality of word lines WL₁ to WL₂ₘ (wherein m is an integer greater than 1), and are arranged in a memory array in the row direction and the column direction. As described in the first embodiment, the source line SL may connect the source of each memory cell in the memory array in series. The bit lines BL₁, BL₃, . . . BLₙ may connect the drains of the memory cells in series. The word lines WL₁, WL₂, . . . WL₂ₘ may connect the gates of the memory cells in series. It should be noted that, as compared with the first embodiment, the body line BdL of this embodiment may be coupled to the third conductive line 76 (as shown in FIG. 6E) to connect a body (e.g. the body region 14 of FIG. 9E) of each memory cell in the memory array in series. That is to say, in addition to applying the drain voltage V_{d}, the source voltage Vₛ, and the gate voltage V_{g}, this embodiment further includes applying the control voltage (e.g. V₁=0V) to the body line transistor BdLT to be provided to a body of a memory cell M2 through the body line BdL, so as to serve as a body voltage V_{b} for controlling a potential of the body.

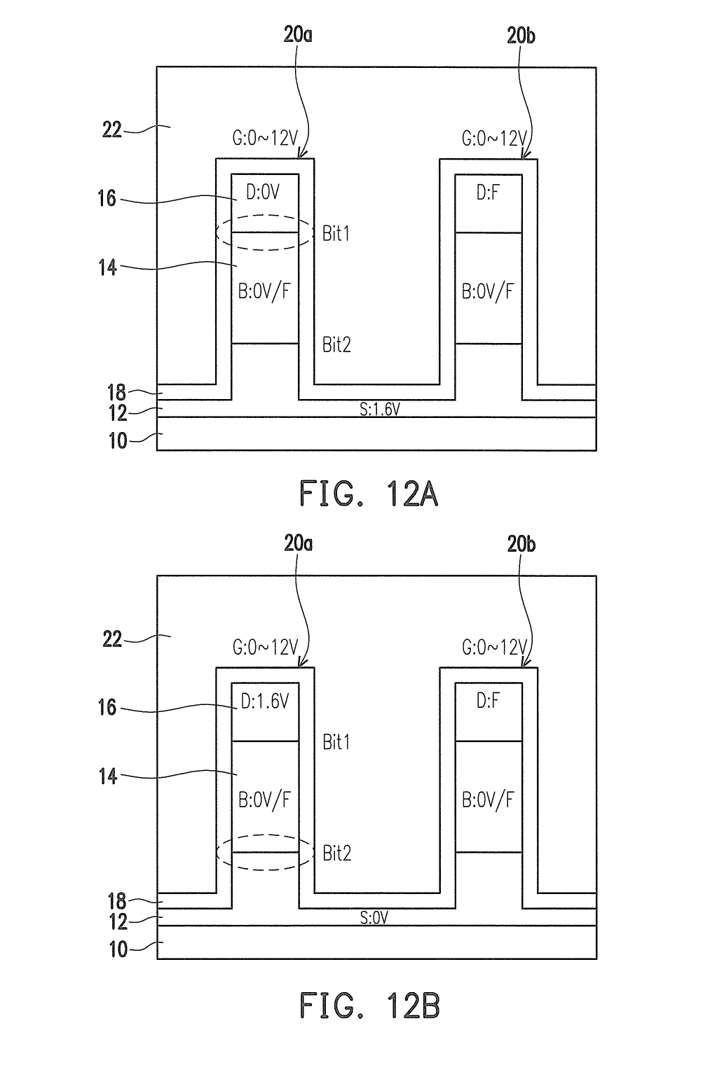

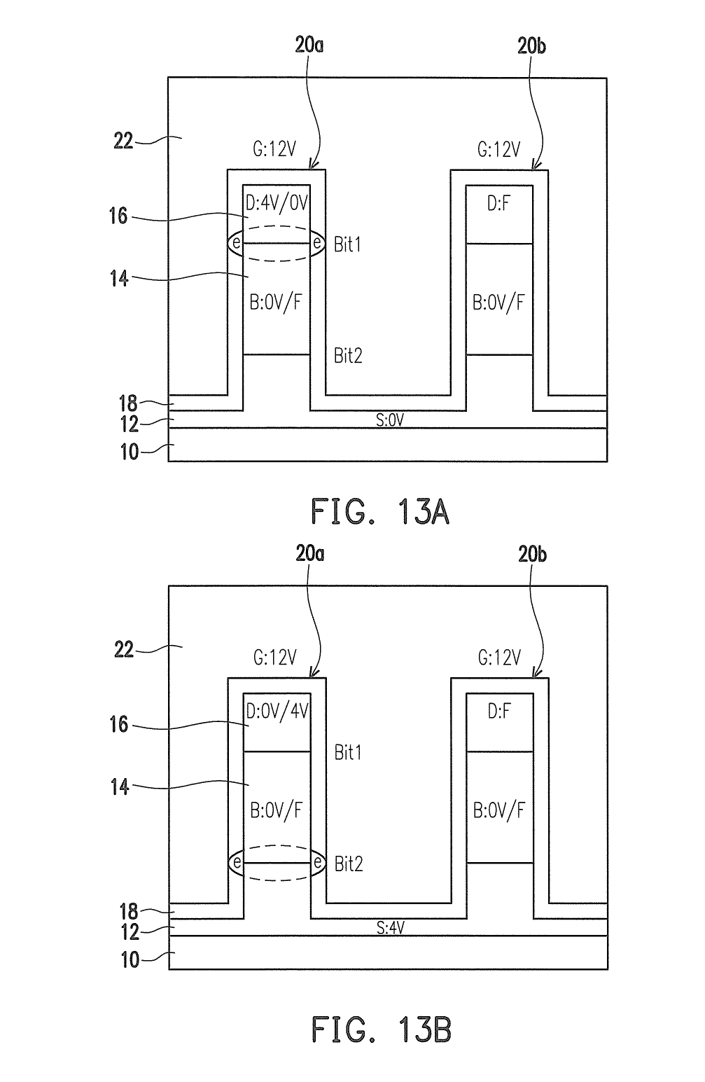

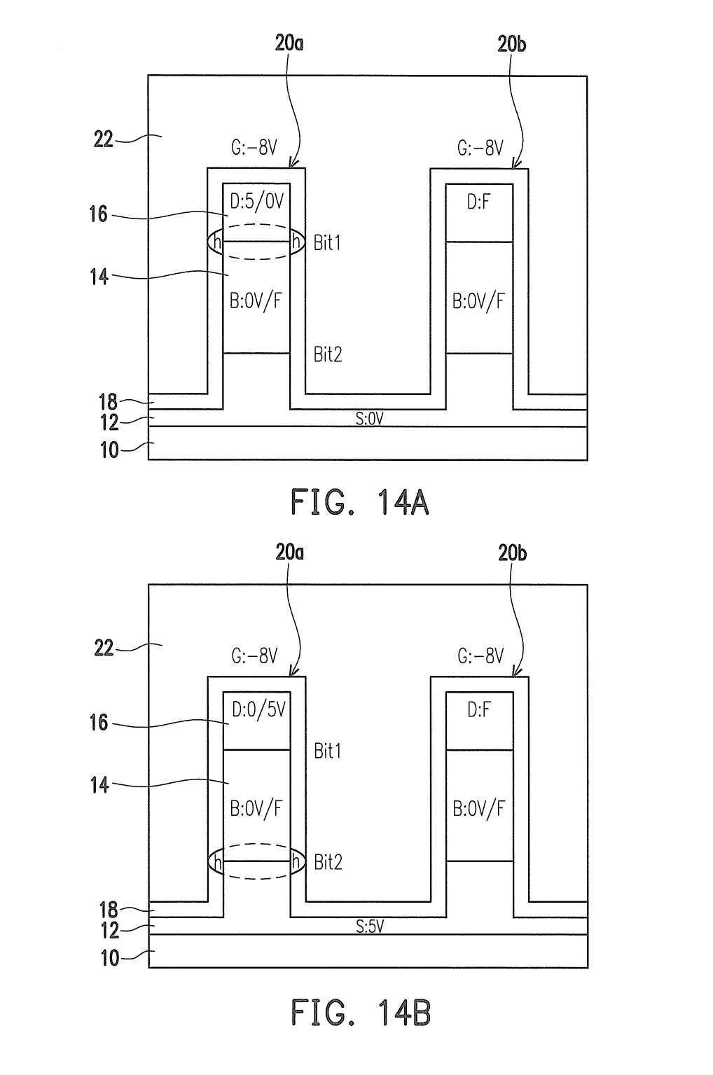

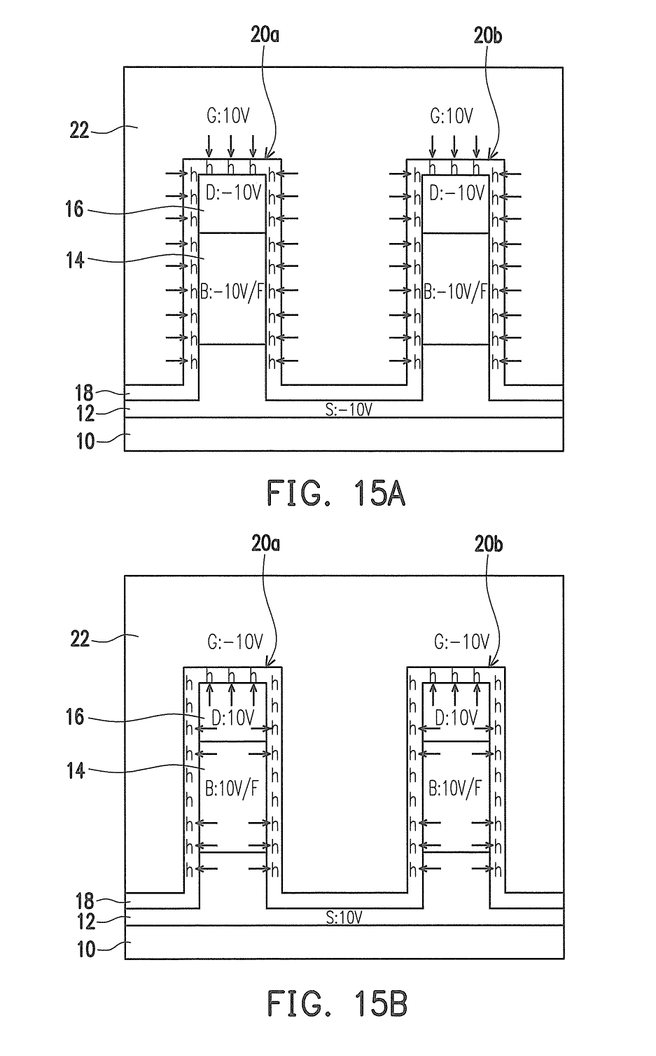

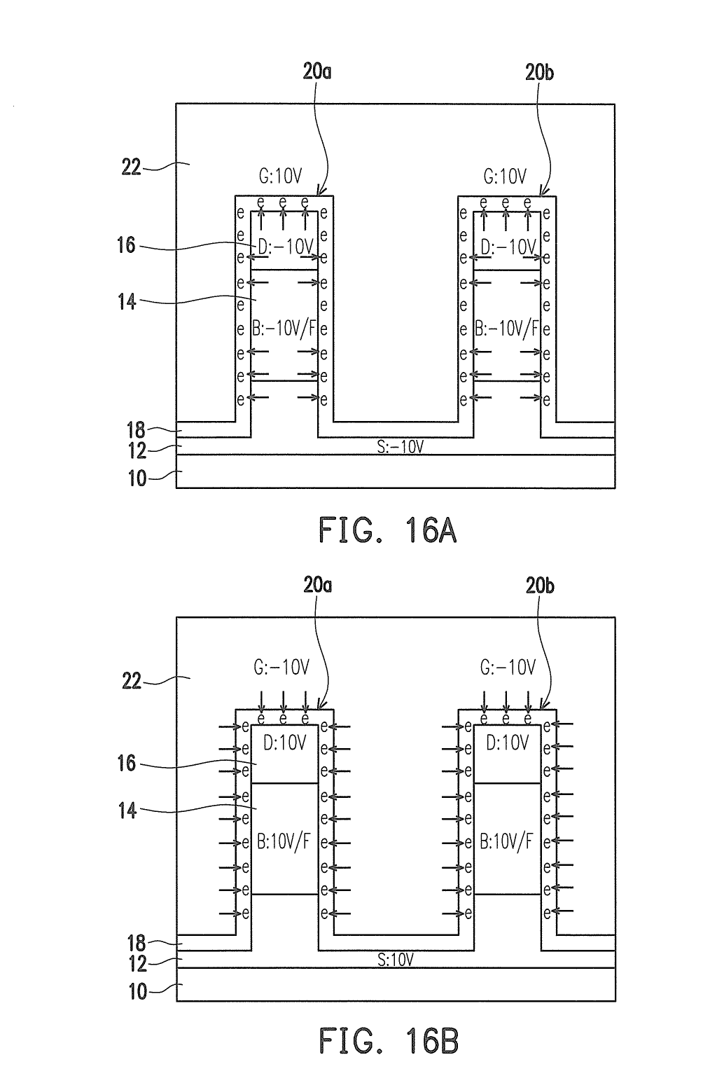

FIG. 12A to FIG. 12B are schematic views illustrating a memory device of a reverse reading (RR) operation according to an embodiment of the invention. FIG. 13A to FIG. 13B are schematic views illustrating a memory device of a channel hot electron injection (CHEI) operation according to an embodiment of the invention. FIG. 14A to FIG. 14B are schematic views illustrating a memory device of a band-to-band tunneling induced hot hole (BTBT HH) operation according to an embodiment of the invention. FIG. 15A to FIG. 15B are schematic views illustrating a memory device of an FN (Fowler-Nordheim) hole injection operation according to an embodiment of the invention. FIG. 16A to FIG. 16B are schematic views illustrating a memory device of an FN electron injection operation according to an embodiment of the invention.

The memory cells M1 and M2 may be programmed or erased by various methods. For example, the memory cells M1 and M2 may be programmed by CHEI or BTBT HH. Moreover, the erasing operation for the memory cells M1 and M2 may be performed by BTBT HH, FN electron injection, or FN hole injection. Table 1 to Table 3 show three operational conditions for reading, programming, and erasing memory cells. It should be noted that the scope of the invention is not limited to the operation methods and operation voltages specified below.

With reference to Table 1, in the operational condition 1, the methods of reading, programming, and erasing the memory cell are RR, CHEI, and BTBT HH, for example.

TABLE 1

| Operational Condition 1 | | Vₛ | | V_{d} | | V_{g} | | V_{b} |
|---|---|---|---|---|---|---|---|---|
| RR | reading bit 1 | 1.6 | V | 0 | V | 0-12 | V | 0 V/F |
| | reading bit 2 | 0 | V | 1.6 | V | 0-12 | V | 0 V/F |

| | | | | | | | |
|---|---|---|---|---|---|---|---|
| CHEI | programming bit 1 | 0 | V | 4 V/0 V | 12 | V | 0 V/F |
| | programming bit 2 | 4 | V | 0 V/4 V | 12 | V | 0 V/F |
| BTBT HH | erasing bit 1 | 0 | V | 5 V/0 V | −8 | V | 0 V/F |
| | erasing bit 2 | 5 | V | 0 V/5 V | −8 | V | 0 V/F |

Referring to FIG. 12A, the structure of a memory device 300 is as illustrated in FIG. 1D or FIG. 6E. A drain of a semiconductor strip structure 20a may be connected with the bit line BL₁ (as shown in FIG. 11A or FIG. 11B), and a semiconductor strip structure 20b may be connected with the bit line BL₃, for example. The bit line transistor BLT₁ is turned on to select the bit line BL₁, so as to provide the voltage applied to the global bit line GBL₁ to the drain of the semiconductor strip structure 20a.

With reference to Table 1 and FIG. 12A, the operational condition of a reading bit 1 for example includes: applying a reading bias to the source end of the selected semiconductor strip structure 20a (the source voltage Vₛ=1.6V), and applying the drain voltage V_{d}=0V to the drain and applying the gate voltage V_{g}=0-12V to the gate to sense charges on the drain-side junction, wherein the body voltage V_{b} may be 0V or in the floating state; and the drain voltage V_{d} of the unselected semiconductor strip structure 20b is in the floating state (F). With reference to FIG. 12B, the operation of a reading bit 2 includes: applying a reading bias to the drain end to sense charges on the source-side junction so as to complete the reading operation.

With reference to Table 1 and FIG. 13A, in the operational condition 1, the memory cell is programmed by CHEI. The operational condition of a programming bit 1 for example includes: applying a gate voltage V_{g}=12V to turn on the channel, and simultaneously applying a drain voltage V_{d}=4V of a middle level, wherein the source voltage Vₛ=0V and the body voltage V_{b}=0V/F, so as to form an electric field from the source to the drain. When the bias between the source and the drain is quite large, excessive hot electrons are generated on the channel, and a portion of the hot electrons inject into the gate for programming. On the other hand, referring to FIG. 13B, the operational condition of a programming bit 2 includes: applying a source voltage Vₛ=4V of a middle level so as to form an electric field from the drain to the source.

With reference to Table 1 and FIG. 14A, in the operational condition 1, the memory cell is erased by BTBT HH. The operational condition of an erasing bit 1 for example includes: applying a gate voltage V_{g}=−8V and simultaneously applying a drain voltage V_{d}=5V. Under such a bias condition, charged carriers are injected to the charge storage layer 18 by BTBT HH for erasing the bit 1. On the other hand, referring to FIG. 14B, the operational condition of an erasing bit 2 includes: applying a source voltage Vₛ=5V.

With reference to Table 2, in the operational condition 2, the methods of reading, programming, and erasing the memory cell are RR, CHEI, and FN hole injection, for example.

TABLE 2

| Operational Condition 2 | | Vₛ | | V_{d} | | V_{g} | | V_{b} | |
|---|---|---|---|---|---|---|---|---|---|
| RR | reading bit 1 | 1.6 | V | 0 | V | 0-12 | V | 0 | V/F |
| | reading bit 2 | 0 | V | 1.6 | V | 0-12 | V | 0 | V/F |
| CHEI | programming bit 1 | 0 | V | 4 V/0 V | | 12 | V | 0 | V/F |
| | programming bit 2 | 4 | V | 0 V/4 V | | 12 | V | 0 | V/F |
| FN hole | +FN erasing | −10 | V | −10 | V | 10 | V | −10 | V/F |
| injection | −FN erasing | 10 | V | 10 | V | −10 | V | 10 | V/F |

In the operational condition 2, the reading operation and the programming operation performed by CHEI has been specified above. Thus, details thereof are not repeated hereinafter.

With reference to Table 2, FIG. 15A, and FIG. 15B, in the operational condition 2, the memory cell may be erased by +FN hole injection or −FN hole injection. Referring to FIG. 15A, the erasing operation performed by +FN hole injection for example includes: injecting holes from a gate 22 to the charge storage layer 18. The operational condition thereof for example includes: applying a gate voltage V_{g}=10V and simultaneously applying a drain voltage V_{d}=−10V, a source voltage Vₛ=−10V, and a body voltage V_{b}=−10V or being floating, so as to form a larger electric field between the source 12 and the gate 22 and between the drain 16 and the gate 22, such that the holes in the gate 22 can enter the charge storage layer 18 through FN tunneling for erasing data. By contrast thereto, referring to FIG. 15B, the erasing operation performed by −FN hole injection for example includes: injecting holes from the source 12, the body 14, and the drain 16 to the charge storage layer 18. The operational condition thereof for example includes: applying a gate voltage V_{g}=−10V and simultaneously applying a drain voltage V_{d}=10V, a source voltage Vₛ=10V, and a body voltage V_{b}=10V or being floating, such that the holes in the source 12, the body 14, and the drain 16 can enter the charge storage layer 18 through FN tunneling for erasing data.

With reference to Table 3, in the operational condition 3, the methods of reading, programming, and erasing the memory cell are RR, BTBT HH, and FN electron injection, for example, as shown in Table 3.

TABLE 3

| Operational Condition 3 | | Vₛ | | V_{d} | | V_{g} | | V_{b} | |
|---|---|---|---|---|---|---|---|---|---|
| RR | reading bit 1 | 1.6 | V | 0 | V | 0-12 | V | 0 | V/F |
| | reading bit 2 | 0 | V | 1.6 | V | 0-12 | V | 0 | V/F |
| BTBT HH | programming bit 1 | 0 | V | 5 V/0 V | | −8 | V | 0 | V/F |
| | programming bit 2 | 5 | V | 0 V/5 V | | −8 | V | 0 | V/F |
| FN electron | +FN erasing | −10 | V | −10 | V | 10 | V | −10 | V/F |
| injection | −FN erasing | 10 | V | 10 | V | −10 | V | 10 | V/F |

In the operational condition 3, the programming operation performed by BTBT HH is similar to the erasing operation performed by BTBT HH in the operational condition 1. Thus, details thereof are not repeated hereinafter.

With reference to Table 3, FIG. 16A, and FIG. 16B, in the operational condition 3, the memory cell may be erased by +FN electron injection or −FN electron injection. Referring to FIG. 16A, the erasing operation performed by +FN electron injection for example includes: injecting electrons from the source 12, the body 14, and the drain 16 to the charge storage layer 18. The operational condition thereof for example includes: applying a gate voltage V_{g}=10V and simultaneously applying a drain voltage V_{d}=−10V, a source voltage Vₛ=−10V, and a body voltage V_{b}=−10V or being floating, so as to form a larger electric field between the source 12 and the drain 16 and the gate 22, such that the electrons in the source 12, the body 14, and the drain 16 can inject into the charge storage layer 18 through FN tunneling for erasing data. By contrast, referring to FIG. 16B, the erasing operation performed by −FN electron injection for example includes: injecting electrons from the gate 22 to the charge storage layer 18. The operational condition thereof for example includes: applying a gate voltage V_{g}=−10V and simultaneously applying a drain voltage V_{d}=10V, a source voltage Vₛ=10V, and a body voltage V_{b}=10V or being floating, so as to inject electrons from the gate 22 to the charge storage layer 18.

In addition, the operations of FN hole injection and FN electron injection can not only be used for erasing data from a memory. Before performing the programming or erasing operation on the memory cell, if a threshold voltage (Vt) of the memory cell does not reach the required value due to process variation or other factors, the method of FN hole or FN electron injection may be used to adjust the threshold voltage, so as to reach the required value. In an embodiment, the threshold voltage may be increased by FN electron injection. In another embodiment, the threshold voltage may be decreased by FN hole injection.

To conclude the above, the invention uses the first contact to electrically connect the source of each semiconductor strip structure. Accordingly, the relative relationship between vertical memory devices and the configuration of the stack structure can be significantly simplified without sacrificing the operational performance and the compatibility with the current fabricating processes. Moreover, by applying voltage to the body through the third conductive line, the potential of the body is controlled. Thus, the potential of the body can be obtained to prevent the potential of the body from becoming a floating state due to the coupling effect of other bias.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

What is claimed is:

1. A memory device, comprising:
a substrate comprising a plurality of first blocks and a plurality of second blocks, wherein the first blocks and the second blocks are alternated to each other, each of the first blocks comprises two first regions and a second region, and the second region is disposed between the two first regions;
a plurality of semiconductor strip structures disposed on the substrate, wherein each of the semiconductor strip structures extends in a first direction;
a first doped region comprising a plurality of first portions and a second portion, wherein each of the first portions is disposed at a lower part of the corresponding semiconductor strip structure, the second portion is disposed on a surface of the substrate, and the first portions are connected with the second portion;
a plurality of second doped regions, wherein each of the second doped regions is disposed at an upper part of the corresponding semiconductor strip structure;
a plurality of word lines disposed on the substrate in each of the first regions, wherein each of the word lines extends in a second direction and covers a portion of a sidewall and a portion of a top of each of the semiconductor strip structures, and the first direction and the second direction are different from each other;
a charge storage layer disposed between the semiconductor strip structures and the word lines;
a plurality of first contacts disposed in the second blocks and the second regions and arranged in the first direction, wherein each of the first contacts is electrically connected with the second portion of the first doped region;
a plurality of second contacts disposed at least in the second regions, wherein each of the second contacts is electrically connected with the corresponding second doped region;
a first conductive line disposed on the substrate, wherein the first conductive line extends in the first direction and is electrically connected with the first contacts; and
a plurality of second conductive lines disposed on the substrate, wherein each of the second conductive lines extends in the first direction and is electrically connected with the second contacts on the corresponding semiconductor strip structure.

2. The memory device according to claim 1, wherein:
each of the semiconductor strip structures comprises a body region disposed between the second doped region and the first portion of the first doped region of the semiconductor strip structure; and
the second contacts further disposed in the second blocks.

3. The memory device according to claim 2, wherein each of the semiconductor strip structures comprises:
a first barrier layer disposed between the body region and the first portion of the first doped region; and
a second barrier layer disposed between the body region and the second doped region.

4. The memory device according to claim 1, wherein:
each of the second blocks comprises a trench therein that extends in the second direction; and
each of the semiconductor strip structures comprises a body region, wherein:
in the first blocks, each of the body regions is disposed between the second doped region and the first portion of the first doped region; and
in the second blocks, each of the body regions is disposed on the first portion of the first doped region, and the trench exposes the body region.

5. The memory device according to claim 4, further comprising:
a plurality of third contacts disposed in the second blocks and extending in the second direction, wherein each of the third contacts is electrically connected with the body regions exposed by the trench; and
a third conductive line disposed on the substrate, wherein the third conductive line extends in the first direction and is electrically connected with the third contacts.

6. The memory device according to claim 5, further comprising:
a plurality of local conductive lines disposed in the first blocks at two sides of each third contact, wherein each of the local conductive lines extends in the first direction and is electrically connected with the second contacts on the corresponding semiconductor strip structure, and
each of the second conductive lines is disposed above the local conductive lines on the corresponding semiconductor strip structure and spans across the third contacts to be electrically connected with the corresponding local conductive lines through a plurality of fourth contacts.

7. The memory device according to claim 4, wherein each of the semiconductor strip structures comprises:
a first barrier layer disposed between the body region and the first portion of the first doped region; and
a second barrier layer disposed between the body region and the second doped region.

8. A fabricating method of a memory device, the fabricating method comprising:
providing a substrate which comprises a plurality of first blocks and a plurality of second blocks, wherein the first blocks and the second blocks are alternated to each other, each of the first blocks comprises two first regions and a second region, and the second region is disposed between the two first regions;
forming a plurality of semiconductor strip structures on the substrate, wherein each of the semiconductor strip structures extends in a first direction;
forming a first doped region which comprises a plurality of first portions and a second portion, wherein each of the first portions is disposed at a lower part of the corresponding semiconductor strip structure, the second portion is disposed on a surface of the substrate, and the first portions are connected with the second portion;
forming a plurality of second doped regions at an upper part of each of the semiconductor strip structures;
forming a plurality of word lines on the substrate in each of the first regions, wherein each of the word lines extends in a second direction and covers a portion of a sidewall and a portion of a top of each of the semiconductor strip structures, and the first direction and the second direction are different from each other;
forming a charge storage layer between the semiconductor strip structures and the word lines;
forming a plurality of first contacts in the second blocks and the second regions, wherein the first contacts are arranged in the first direction and each of the first contacts is electrically connected with the second portion of the first doped region;
forming a plurality of second contacts at least in the second regions, wherein each of the second contacts is electrically connected with the corresponding second doped region;
forming a first conductive line on the substrate, wherein the first conductive line extends in the first direction and is electrically connected with the first contacts; and
forming a plurality of second conductive lines on the substrate, wherein each of the second conductive lines extends in the first direction and is electrically connected with the second contacts on the corresponding semiconductor strip structure.

9. The fabricating method according to claim 8, wherein a method of forming the semiconductor strip structures, the first doped region, and the second doped regions comprises:
patterning a portion of the substrate to form the semiconductor strip structures;
performing an ion implantation process to implant a dopant into the upper part of each of the semiconductor strip structures and a surface of the substrate; and
performing a thermal annealing process to form the first doped region and the second doped regions.

10. The fabricating method according to claim 8, wherein a method of forming the semiconductor strip structures, the first doped region, and the second doped regions comprises:
performing an ion implantation process to form the second portion of the first doped region on the surface of the substrate;
forming a stack layer on the substrate, wherein the stack layer comprises a first doped layer, a body layer, and a second doped layer in sequence from bottom to top; and
patterning the stack layer to form the first portions of the first doped region, a plurality of body regions, and the second doped regions.

11. The fabricating method according to claim 8, further comprising: forming the second contacts in the second blocks.

12. The fabricating method according to claim 8, further comprising:
removing a portion of the semiconductor strip structures in the second blocks to form a trench that extends in the second direction, wherein the trench exposes the body regions of the corresponding semiconductor strip structures.

13. The fabricating method according to claim 12, further comprising:
forming a plurality of third contacts in the second blocks, wherein each of the third contact extends in the second direction and is electrically connected with the body regions exposed by the trench; and
forming a third conductive line on the substrate, wherein the third conductive line extends in the first direction and is electrically connected with the third contacts.

14. The fabricating method according to claim 13, further comprising:
forming a plurality of local conductive lines in the first blocks at two sides of each third contact, wherein each of the local conductive lines extends in the first direction and is electrically connected with the second contacts on the corresponding semiconductor strip structure, and
each of the second conductive lines is disposed above the local conductive lines on the corresponding semiconductor strip structure and spans across the third contacts to be electrically connected with the corresponding local conductive lines through a plurality of fourth contacts.

15. The fabricating method according to claim 10, wherein the stack layer comprises the first doped layer, a first barrier layer, the body layer, a second barrier layer, and the second doped layer in sequence from bottom to top.

16. A memory device, comprising:
a substrate comprising a plurality of first blocks and a plurality of second blocks, wherein the first blocks and the second blocks are alternated to each other, each of the first blocks comprises two first regions and a second region, and the first regions and the second regions is disposed between the two first regions;
a plurality of semiconductor strip structures disposed on the substrate, wherein each of the semiconductor strip structures extends in a first direction;
a first doped region comprising a plurality of first portions and a second portion, wherein each of the first portions is disposed at a lower part of the corresponding semiconductor strip structure, the second portion is disposed on a surface of the substrate, and the first portions are connected with the second portion;
a plurality of second doped regions, wherein each of the second doped regions is disposed at an upper part of the corresponding semiconductor strip structure;
a first conductive line disposed on the substrate, wherein the first conductive line extends in the first direction and is electrically connected with the second portion of the first doped region in the second blocks and the second regions; and
a plurality of second conductive lines disposed on the substrate, wherein each of the second conductive lines extends in the first direction and is electrically connected with the second doped regions on the corresponding semiconductor strip structure in the second regions.

17. The memory device according to claim 16, wherein:
each of the second conductive lines is further electrically connected with the second doped region on the corresponding semiconductor strip structure in the second regions.

18. The memory device according to claim 16, wherein:
each of the second blocks comprises a trench therein that extends in the second direction;
each of the semiconductor strip structures comprises a body region, wherein:
in the first blocks, each of the body regions is disposed between the second doped region and the first portion of the first doped region; and
in the second blocks, each of the body regions is disposed on the first portion of the first doped region, and the trench exposes the body region; and
a third conductive line is disposed on the substrate, wherein the third conductive line extends in the first direction and is electrically connected with the body regions exposed by the trench in the second blocks.

19. The memory device according to claim 18, further comprising:
a plurality of local conductive lines disposed in the first blocks, wherein each of the local conductive lines extends in the first direction and is electrically connected with the second doped region on the corresponding semiconductor strip structure, and
each of the second conductive lines is disposed above the local conductive lines on the corresponding semiconductor strip structure and spans across the second blocks to be electrically connected with the corresponding local conductive lines in the first blocks.

20. The memory device according to claim 16, wherein each of the semiconductor strip structures comprises:
a body region disposed between the second doped region and the first portion of the first doped region;
a first barrier layer disposed between the body region and the first portion of the first doped region; and
a second barrier layer disposed between the body region and the second doped region.

21. A memory array comprising the memory device of claim 1 the memory array further comprising:
a plurality of memory cells arranged in an array of a plurality of columns and a plurality of rows and comprising the first doped region as a source and the second doped regions as a drain;
a plurality of bit lines each coupled to the second doped regions of the memory cells of the same column;
a plurality of common source lines each coupled to the first doped region of the memory cells of the same row; and
a source line coupled to the common source lines and electrically connected with the first doped region of the memory cells,
wherein each word line is coupled to a plurality of gates of the memory cells of the same row.

22. The memory array according to claim 21, further comprising a body line coupled to a plurality of body regions of the memory cells.

23. An operating method of the memory array of claim 21, comprising:
selecting at least one memory cell;
applying a first voltage to a word lines corresponding to the selected at least one memory cell;
applying a second voltage to a bit lines corresponding to the selected at least one memory cell; and
applying a third voltage to the source line of the memory array.

24. The operating method according to claim 23, further comprising applying a fourth voltage to a body line of the memory array corresponding to the selected at least one memory cell.
